(19) United States
(12) Patent Application Publication
(10) Pub. No.: US 2024/0297265 A1
(43) Pub. Date: Sep. 5, 2024

(54) DEVICE STRUCTURE FOR SENSING INFRARED LIGHT AND METHOD OF SENSING INFRARED LIGHT

(71) Applicant: National Yang Ming Chiao Tung University, Hsinchu City (TW)

(72) Inventors: Ya-Hsiang TAI, Miaoli County (TW); Yi-Cheng YUAN, New Taipei City (TW)

(21) Appl. No.: 18/369,167

(22) Filed: Sep. 16, 2023

(30) Foreign Application Priority Data
Mar. 1, 2023 (TW) 112107322
May 9, 2023 (TW) 112117232

(51) Int. Cl. H01L 31/101; H01L 31/0224

(52) U.S. Cl. CPC H01L 31/101; H01L 31/022408

(57) ABSTRACT

The present disclosure relates to a device structure for sensing infrared light. The device structure includes a substrate, a first metal electrode, a second metal electrode, and a semiconductor layer. The first metal electrode and the second metal electrode are located on the substrate. The semiconductor layer is located on the substrate, in which the semiconductor layer is located between the first metal electrode and the second metal electrode and above the first metal electrode and the second metal electrode. The semiconductor layer directly contacts the first metal electrode and the second metal electrode.

### CROSS-REFERENCE TO RELATED APPLICATION

This application claims priority to Taiwan Application Serial Number 112107322 filed Mar. 1, 2023, and Taiwan Application Serial Number 112117232 filed May 9, 2023, which are herein incorporated by reference in their entireties.

### BACKGROUND

### Field of Invention

The present disclosure relates to a device structure for sensing infrared light and a method of sensing infrared light.

### Description of Related Art

Sensing infrared light has many applications, for example, fingerprint identification on the display panels, biomedical sensors of heart rate sensing, thermal sensors, and so on. A good infrared sensing device should have high photosensitive efficiency, for example, high external quantum efficiency (EQE). However, conventional photosensitive elements, for example, photodiodes, are limited by exciting one electron with one photon for creating one electron-hole pair, so the external quantum efficiency has an upper limit and cannot exceed 100%. In addition, the traditional photodiodes, for example, PIN photodiodes, include two electrodes, respectively, on the top and the bottom of the sensing layer, so the process variation is limited and may not be compatible with most semiconductor processes, for example, not compatible with the glass panels, the flexible panels, and so on. Therefore, a novel device structure for sensing infrared light and a method for sensing infrared light using this novel device structure are needed to have a device structure with higher external quantum efficiency, sensing weaker infrared light, and including more process variations to be compatible with the nowadays semiconductor processes.

### SUMMARY

The present disclosure provides a device structure for sensing infrared light. The device structure includes a substrate, a first metal electrode and a second metal electrode on the substrate, and a semiconductor layer on the substrate, in which the semiconductor layer is located between and above the first metal electrode and the second metal electrode, the semiconductor layer is in direct contact with the first metal electrode and the second metal electrode, the first metal electrode and the second metal electrode independently include aluminum, nickel, titanium, molybdenum, chromium, gold, silver, copper, or combinations thereof, respectively, and the semiconductor layer includes InSb, InAs, HgCdTe, PbS, PbSe, Ge, Si, GaSb, InGaAs, InTlAs, InAsSb, GaAsSb, InAsP, InGaAsP, GaInSb, AlGaAsSb, AlInSb, GaAsP, AlGaAs, AlAsSb, pentacene, anthracene, tetracene, perylene, tetrahydro-2,3-naphtho[1,2-d][1,4]diazepine, benzo[c][1,2,5]thiadiazepine, poly(3-hexylthiophene), phenyl-C₆₁-butyric acid methyl ester, poly[[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]], poly[2-methoxy-5-(2′-ethylhexyloxy)-1,4-phenylenevinylene], poly(3,4-ethylenedioxythiophene) polystyrene sulfonate, poly[N-9′-heptadecanyl -2,7-carbazole-alt-5,5-(4′,7′-di-2-thienyl-2′,1′,3′-benzothiadiazole)], CuInSe₂, CuInS₂, CuGaSe₂, CuGaS₂, Cu₂ZnSnS₄, Cu₂ZnSnSe₄, Bi₂Te₃, Sb₂Te₃, ZnO, ZnTe, CdTe, CdSe, CdS, SnS, SnSe, TiO₂, CsPbBr₃, CsPbI₃, AgGaSe₂, AgGaS₂, a molybdenum disulfide two-dimensional material, a carbon nanotube, mercury telluride, or combinations thereof.

In some embodiments, the substrate is formed by a process with a process temperature smaller than 600° C., and the substrate includes quartz, plastic, stainless steel, crystalline silicon, sapphire, gallium nitride, or combinations thereof.

In some embodiments, the device structure further includes a third metal electrode on the substrate and an insulating layer on the substrate, in which the third metal electrode is separated from the first metal electrode and the second metal electrode by the insulating layer, a semiconductor layer projection of the semiconductor layer on the substrate has a middle portion between a first metal electrode projection of the first metal electrode on the substrate and a second metal electrode projection of the second metal electrode on the substrate, the third metal electrode has a third metal electrode projection on the substrate, and all the middle portion overlaps with the third metal electrode projection.

In some embodiments, the device structure further includes at least one third metal electrode on the substrate and an insulating layer on the substrate. The semiconductor layer has a middle portion between the first metal electrode and the second metal electrode, the middle portion includes at least one first portion and at least one second portion, a projection of the at least one first portion on the substrate does not overlap with a third metal electrode projection of the at least one third metal electrode on the substrate, and a projection of the at least one second portion on the substrate overlaps with the third metal electrode projection. The at least one third metal electrode is separated from the first metal electrode and the second metal electrode by the insulating layer.

In some embodiments, a projection area of each one of the at least one first portion on the substrate is smaller than 100 μm².

The present disclosure also provides a method of sensing infrared light. The method includes the following operations. The device structure is irradiated with a light source, in which when the substrate includes an opaque substrate, the light source is incident towards a side of the semiconductor layer facing away from the substrate, and when the substrate includes a transparent substrate, the light source is incident towards the side of the semiconductor layer facing away from the substrate, a side of the semiconductor layer facing the substrate, or a combination thereof. A first intensity of the light source is adjusted to a second intensity to adjust a first energy barrier on a contact surface of the semiconductor layer with the first metal electrode and the second metal electrode to a second energy barrier, in which the second intensity is larger than the first intensity, and the second energy barrier is smaller than the first energy barrier.

The present disclosure also provides a method of sensing infrared light. The method includes the following operations. The device structure is irradiated with a light source. A positive bias voltage or a negative bias voltage is applied to the third metal electrode. A first intensity of the light source is adjusted to a second intensity to adjust a first energy barrier on a contact surface of the semiconductor layer with the first metal electrode and the second metal electrode to a second energy barrier, in which the second intensity is larger than the first intensity, and the second energy barrier is smaller than the first energy barrier.

In some embodiments, the positive bias voltage is from +0.5 V to +25 V, and the negative bias voltage is from −0.5 V to −5 V.

The present disclosure also provides a method of sensing infrared light. The method includes the following operations. The device structure is irradiated with a light source. A positive bias voltage or a negative bias voltage is applied to the at least one third metal electrode. A first intensity of the light source is adjusted to a second intensity to adjust a first energy barrier on a contact surface of the semiconductor layer with the first metal electrode and the second metal electrode to a second energy barrier and to adjust a third energy barrier on a contact surface between the at least one first portion and the at least one second portion to a fourth energy barrier, in which the second intensity is larger than the first intensity, the second energy barrier is smaller than the first energy barrier, and the fourth energy barrier is smaller than the third energy barrier.

The present disclosure also provides a device structure for sensing infrared light. The device structure includes a transparent substrate, a first metal electrode and a second metal electrode on the transparent substrate, and a semiconductor layer on the transparent substrate, in which the semiconductor layer is located below the first metal electrode and the second metal electrode, the semiconductor layer is in direct contact with the first metal electrode and the second metal electrode, the first metal electrode and the second metal electrode independently include aluminum, nickel, titanium, molybdenum, chromium, gold, silver, copper, or combinations thereof, respectively, and the semiconductor layer includes InSb, InAs, HgCdTe, PbS, PbSe, Ge, Si, GaSb, InGaAs, InTlAs, InAsSb, GaAsSb, InAsP, InGaAsP, GaInSb, AlGaAsSb, AlInSb, GaAsP, AlGaAs, AlAsSb, pentacene, anthracene, tetracene, perylene, tetrahydro-2,3-naphtho[1,2-d][1,4]diazepine, benzo[c][1,2,5]thiadiazepine, poly(3-hexylthiophene), phenyl-C₆₁-butyric acid methyl ester, poly[[4,8-bis[(2-ethylhexyl)oxy]benzo[1,2-b:4,5-b′]dithiophene-2,6-diyl][3-fluoro-2-[(2-ethylhexyl) carbonyl]thieno[3,4-b]thiophenediyl]], poly[2-methoxy-5-(2′-ethylhexyloxy)-1,4-phenylenevinylene], poly(3,4-ethylenedioxythiophene) polystyrene sulfonate, poly[N-9′-heptadecanyl-2,7-carbazole-alt-5,5-(4′,7′-di-2-thienyl-2′,1′,3′-benzothiadiazole)], CuInSe₂, CuInS₂, CuGaSe₂, CuGaS₂, Cu₂ZnSnS₄, Cu₂ZnSnSe₄, Bi₂Te₃, Sb₂Te₃, ZnO, ZnTe, CdTe, CdSe, CdS, SnS, SnSe, TiO₂, CsPbBr₃, CsPbI₃, AgGaSe₂, AgGaS₂, a molybdenum disulfide two-dimensional material, a carbon nanotube, mercury telluride, or combinations thereof.

In some embodiments, the device structure further includes a third metal electrode on the transparent substrate and an insulating layer on the transparent substrate, in which the third metal electrode is separated from the first metal electrode and the second metal electrode by the insulating layer, a semiconductor layer projection of the semiconductor layer on the transparent substrate has a middle portion between a first metal electrode projection of the first metal electrode on the transparent substrate and a second metal electrode projection of the second metal electrode on the transparent substrate, the third metal electrode has a third metal electrode projection on the transparent substrate, and all the middle portion overlaps with the third metal electrode projection.

In some embodiments, the device structure further includes at least one third metal electrode on the transparent substrate and an insulating layer on the transparent substrate. The semiconductor layer has a middle portion between the first metal electrode and the second metal electrode, the middle portion includes at least one first portion and at least one second portion, a projection of the at least one first portion on the transparent substrate does not overlap with a third metal electrode projection of the at least one third metal electrode on the transparent substrate, and a projection of the at least one second portion on the transparent substrate overlaps with the third metal electrode projection. The at least one third metal electrode is separated from the first metal electrode and the second metal electrode by the insulating layer.

The present disclosure also provides a method of sensing infrared light. The method includes the following operations. The device structure is irradiated with a light source, in which the light source is incident towards a side of the semiconductor layer facing the transparent substrate. A first intensity of the light source is adjusted to a second intensity to adjust a first energy barrier on a contact surface of the semiconductor layer with the first metal electrode and the second metal electrode to a second energy barrier, in which the second intensity is larger than the first intensity, and the second energy barrier is smaller than the first energy barrier.

The present disclosure also provides a method of sensing infrared light. The method includes the following operations. The device structure is irradiated with a light source. A positive bias voltage or a negative bias voltage is applied to the third metal electrode. A first intensity of the light source is adjusted to a second intensity to adjust a first energy barrier on a contact surface of the semiconductor layer with the first metal electrode and the second metal electrode to a second energy barrier, in which the second intensity is larger than the first intensity, and the second energy barrier is smaller than the first energy barrier.

The present disclosure also provides a method of sensing infrared light. The method includes the following operations. The device structure is irradiated with a light source. A positive bias voltage or a negative bias voltage is applied to the at least one third metal electrode. A first intensity of the light source is adjusted to a second intensity to adjust a first energy barrier on a contact surface of the semiconductor layer with the first metal electrode and the second metal electrode to a second energy barrier and to adjust a third energy barrier on a contact surface between the at least one first portion and the at least one second portion to a fourth energy barrier, in which the second intensity is larger than the first intensity, the second energy barrier is smaller than the first energy barrier, and the fourth energy barrier is smaller than the third energy barrier.

Referring to the following description and the attached claims can better understand the embodiments, features, and advantages of the present disclosure.

It should be understood that the general description provided above and the specific description shown below are exemplary and illustrative and are intended to provide further explanations for the present disclosure.

### BRIEF DESCRIPTION OF THE DRAWINGS

When reading the figures of the present disclosure, it is recommended to understand the various aspects of the present disclosure from the following description. It is important to note that according to industry standard practice, various sizes of the features may not be drawn to scale. To make the discussion clearly, various sizes of the features may be drawn to increase or decrease intentionally. In addition, to simplify the figures, the customary structure and components may be drawn in a schematic manner.

FIG. 1 is a cross-sectional view of the device structure for sensing infrared light according to some embodiments of the present disclosure.

FIG. 2 is a schematic diagram of the energy levels between the semiconductor layer with the first metal electrode or the second metal electrode in the device structure for sensing infrared light according to some embodiments of the present disclosure.

FIGS. 3 and 4 are cross-sectional views of the device structure for sensing infrared light according to a first embodiment of the present disclosure.

FIGS. 5A, 5B, 50, 6A, 6B, and 6C are cross-sectional views of the device structure for sensing infrared light according to a second embodiment of the present disclosure.

FIG. 7 is a schematic diagram of the energy levels of the semiconductor layer in the device structure for sensing infrared light according to some embodiments of the present disclosure.

FIG. 8 is a cross-sectional view of the device structure for sensing infrared light according to some embodiments of the present disclosure.

FIGS. 9 and 10 are cross-sectional views of the device structure for sensing infrared light according to a third embodiment of the present disclosure.

FIGS. 11A, 11B, 11C, 12A, 12B, and 12C are cross-sectional views of the device structure for sensing infrared light according to a fourth embodiment of the present disclosure.

FIGS. 13A, 13B, 13C, 14A, and 14B are current versus voltage diagrams changing with illuminance, intensity, or power in the device structure for sensing infrared light according to some embodiments of the present disclosure.

FIG. 15 is a diagram of current per unit area changing with intensity in the device structure for sensing infrared light according to some embodiments of the present revelation.

### DETAILED DESCRIPTION

To make the description of the present disclosure more detailed and complete, the following provides an illustrative description of the aspects of the embodiments and the specific embodiments. This is not to limit the implementation of the present disclosure to only one form. The embodiments of the present disclosure may be combined or substituted with each other under beneficial situations, and other embodiments may be added without further statement or explanation.

In addition, spatially relative terms, for example, below, above, and so on, may describe the relationship of one component/feature to another component/feature in the figures of the present disclosure. Besides the orientation described in the figures, spatially relative terms intend to cover different orientations of the device in use or in operation. For example, the device may be oriented in other ways (e.g., rotating 90 degrees or in other directions), and the spatially relative terms of the present disclosure can be interpreted accordingly. In the present disclosure, unless otherwise stated, the same reference numbers shown in the different figures are the same or similar components formed by the same or similar methods with the same or similar materials.

In addition, taking into account the errors, for example, the errors caused by the measurements or actual operation, the “approximately”, “nearly”, “basically”, or “substantially” used in the present disclosure include the values/characteristics and the values/characteristics within a range of deviations acceptable by one skilled in the art. For example, the value is within a range of deviations of +15%, +15%, or +5%. The acceptable deviation may be selected depending on the nature of the measurement or others affecting the operation.

The present disclosure provides a device structure for sensing infrared light. The device structure includes a substrate, a first metal electrode and a second metal electrode on the substrate, and a semiconductor layer on the substrate, in which the semiconductor layer is located between and above the first metal electrode and the second metal electrode, the semiconductor layer is in direct contact with the first metal electrode and the second metal electrode, the first metal electrode and the second metal electrode independently include aluminum, nickel, titanium, molybdenum, chromium, gold, silver, copper, or combinations thereof, respectively, and the semiconductor layer includes InSb, InAs, HgCdTe, PbS, PbSe, Ge, Si, GaSb, InGaAs, InTlAs, InAsSb, GaAsSb, InAsP, InGaAsP, GaInSb, AlGaAsSb, AlInSb, GaAsP, AlGaAs, AlAsSb, pentacene, anthracene, tetracene, perylene, tetrahydro-2,3-naphtho[1,2-d][1,4]diazepine, benzo[c][1,2,5]thiadiazepine, poly(3-hexylthiophene) (P3HT), phenyl-C₆₁-butyric acid methyl ester (PCBM), poly[4,8-bis[(2-ethylhexyl)oxy]benzo[1,2-b:4,5-b′]dithiophene-2,6-diyl][3-fluoro-2-[(2-ethylhexyl) carbonyl]thieno[3,4-b]thiophenediyl] (PTB7), poly[2-methoxy-5-(2′-ethylhexyloxy)-1,4-phenylenevinylene] (MEH-PPV), poly(3,4-ethylenedioxythiophene) polystyrene sulfonate (PEDOT:PSS), poly[N-9′-heptadecanyl-2,7-carbazole-alt-5,5-(4′,7′-di-2-thienyl-2′,1′,3′-benzothiadiazole)] (PCDTBT), CuInSe₂, CuInS₂, CuGaSe₂, CuGaS₂, Cu₂ZnSnS₄, Cu₂ZnSnSe₄, Bi₂Te₃, Sb₂Te₃, ZnO, ZnTe, CdTe, CdSe, CdS, SnS, SnSe, TiO₂, CsPbBr₃, CsPbI₃, AgGaSe₂, AgGaS₂, a molybdenum disulfide two-dimensional material, a carbon nanotube, mercury telluride, or combinations thereof. The device structure is described in detail according to some embodiments in the following.

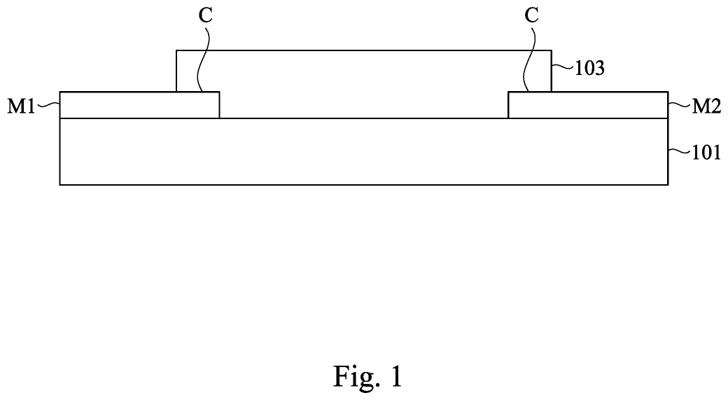

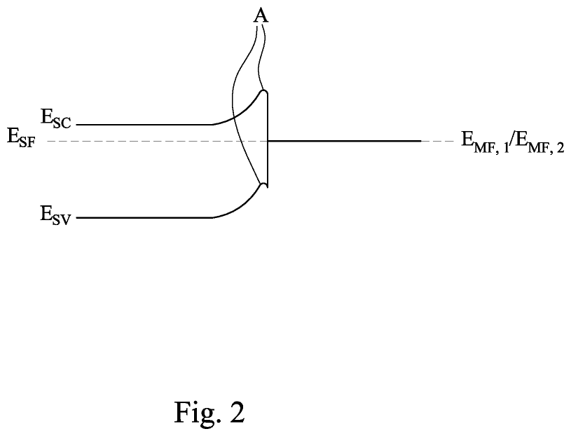

FIG. 1 is a cross-sectional view of the device structure according to some embodiments of the present disclosure. In FIG. 1, the device structure includes a substrate 101, a first metal electrode M1, a second metal electrode M2, and a semiconductor layer 103, in which the lower surface of the first metal electrode M1, the lower surface of the second metal electrode M2, and the lower surface of the semiconductor layer 103 are on the same plane. FIG. 2 is a schematic diagram of the energy levels between the semiconductor layer 103 with the first metal electrode M1 or the second metal electrode M2 according to some embodiments of the present disclosure. The device structure is described in detail in the following with reference to FIGS. 1 and 2.

Firstly, the substrate 101 is described. In some embodiments, the substrate 101 is formed by a process with a process temperature smaller than 600° C., for example, smaller than 550° C., smaller than 500° C., or smaller than 450° C., etc. Since the process temperature is not necessary to be very high, the process cost is reduced. In some embodiments, the substrate 101 includes a transparent substrate or an opaque substrate. In some embodiments, the substrate 101 includes quartz (or glass), plastic (e.g., polyimide, etc.), stainless steel, crystalline silicon, sapphire, gallium nitride, or combinations thereof. In some embodiments, the substrate 101 further includes an active component (e.g., a diode or a transistor, etc.), a passive component (e.g., a resistor, a capacitor, or an inductor, etc.), a conductive structure (e.g., a wire, etc.), or combinations thereof.

Next, the semiconductor layer 103 is described. The semiconductor layer 103 is on the substrate 101 and is located between and above the first metal electrode M1 and the second metal electrode M2. Since the entire semiconductor layer 103 is exposed from the first metal electrode M1 and the second metal electrode M2, the material of the semiconductor layer 103 can be easily replaced at any time in need without removing the first metal electrode M1 and the second metal electrode M2. The semiconductor layer 103 has an energy gap of about 0.1 eV to about 3 eV, for example, 3.0 eV, 2.5 eV, 2.0 eV, 1.5 eV, 1.2 eV, 1.0 eV, 0.8 eV, 0.6 eV, 0.4 eV, 0.2 eV, or 0.1 eV, etc. to absorb wavelengths including the infrared light from about 400 nm to about 12400 nm.

Next, the first metal electrode M1 and the second metal electrode M2 are described. The first metal electrode M1 and the second metal electrode M2 are on the substrate 101 and are in direct contact with the semiconductor layer 103. In some embodiments, the first metal electrode M1 and the second metal electrode M2 are separated from each other. In some embodiments, the material of the first metal electrode M1 is the same or different from the material of the second metal electrode M2. When the material of the first metal electrode M1 is the same as the material of the second metal electrode M2, the method of forming the device structure may include simultaneously forming the first metal electrode M1 and the second metal electrode M2 to simplify the process and reduce costs.

When the semiconductor layer 103 of FIG. 1 is in direct contact with the first metal electrode M1 and the second metal electrode M2, the energy levels on the contact surface C of the semiconductor layer 103 with the first metal electrode M1 and the second metal electrode M2 are illustrated with reference to FIG. 2. In FIG. 2, E_{SC} is the energy level of the conduction band of the semiconductor layer 103, E_{SV} is the energy level of the valence band of the semiconductor layer 103, E_{SF} is the Fermi energy level of the semiconductor layer 103, E_{MF,1} is the Fermi energy level of the first metal electrode M1, and E_{MF,2} is the Fermi energy level of the second metal electrode M2. When the semiconductor layer 103 is in direct contact with the first metal electrode M1 and the second metal electrode M2, the energy levels of the semiconductor layer 103 on the contact surface C bend and deform to form an energy barrier A as shown in FIG. 2; therefore, the Fermi energy level E_{SF} of the semiconductor layer 103 is in equilibrium with the Fermi energy level E_{MF,1} of the first metal electrode M1 and the Fermi energy level E_{MF,2} of the second metal electrode M2 (equivalent to the E_{SF} substantially equal to E_{MF,1} and E_{MF,2}).

The energy barrier A is described in detail. The energy barrier A is a highland portion protruding from the surfaces of the bent and deformed energy levels of the conduction band E_{SC} and the valence band E_{SV} of the semiconductor layer 103. The highland portion obstructs the migration of electrons and/or holes between the semiconductor layer 103 with the first metal electrode M1 and the second metal electrode M2. However, irradiating the device structure with the infrared light can make the energy barrier A become smaller, that is reducing the highland portion protruding from the surfaces of the energy levels to facilitate the migration of electrons and/or holes between the semiconductor layer 103 with the first metal electrode M1 and the second metal electrode M2. In addition, the energy barrier A becomes much smaller with the increase of photon irradiation (e.g., the increase of illuminance, intensity, or power, etc.), so the photocurrents between the semiconductor layer 103 with the first metal electrode M1 and the second metal electrode M2 can increase with the increase of photon irradiation. Specifically, when photons excite electrons to the energy levels of the conduction band E_{SC} and form electron holes on the energy level of the valence band E_{SV}, more and more electron holes gather on the energy barrier A as the photons increase to make the energy barrier A gradually reduces, so the number of electrons that can across the energy barrier A also gradually increases, namely the increase of photocurrent as the increase of photon irradiation. By reducing the energy barrier A with the irradiation of photons to sense the infrared light, the device structure has excellent photoelectric conversion efficiency, for example, larger than 100% external quantum efficiency, and can still generate photocurrent in the environments of weak light, for example, those where the illuminance, the intensity, or the power are substantially equal to zero.

The description of the device structure is continued. In some embodiments, the device structure may be repeatedly arranged on the plane parallel to the substrate 101 to form a repeating array as a matrix. In some embodiments, a collimator (not drawn in figures), a lens (not drawn in figures), or a combination thereof are located above the device structure to improve the accuracy of sensing infrared light or to focus the incident light on the device structure to enhance the sensing intensity.

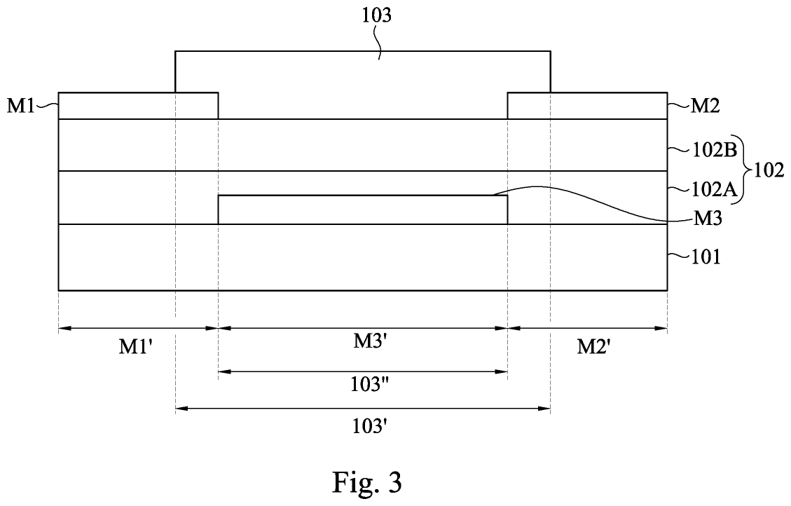

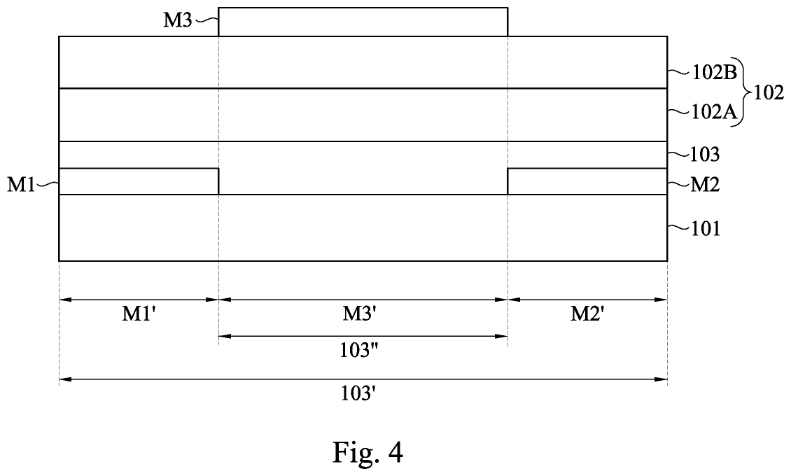

Further, a first embodiment of the device structure shown in FIG. 1 is illustrated with reference to FIGS. 3 and 4, in which the device structure of the first embodiment further includes a third metal electrode M3 and an insulating layer 102 on the substrate 101. The difference between FIG. 3 and FIG. 4 is that the third metal electrode M3 and the insulating layer 102 on the substrate 101 have different positions relative to the first metal electrode M1, the second metal electrode M2, and the semiconductor layer 103 (described in detail later). Regardless of which kind of aspect of the device structure, the device structure can sense the infrared light well as described above, which makes the method of forming the device structure include a variety of options and makes the device structure applicable to a variety of different processes.

The third metal electrode M3 of the first embodiment is continually illustrated with reference to FIGS. 3 and 4. The method of sensing infrared light using the device structure of the first embodiment includes applying a voltage or not applying a voltage to the third metal electrode M3. When a voltage is applied, the current between the first metal electrode M1, the second metal electrode M2, and the semiconductor layer 103 increases. However, regardless of whether a voltage is applied, the energy barrier A between the semiconductor layer 103 with the first metal electrode M1 and the second metal electrode M2 reduces by irradiating with photons, so the photocurrent increases. In addition, the third metal electrode M3 can block the light from the opposite direction of the light source that is intended to measure, thereby avoiding the sensing error caused by the light in the opposite direction of the light source and improving the accuracy of the device structure sensing the infrared light. In some embodiments, the third metal electrode M3 includes aluminum, nickel, titanium, molybdenum, chromium, gold, silver, copper, or combinations thereof.

The insulating layer 102 of the first embodiment is continually described with reference to FIGS. 3 and 4. The insulating layer 102 separates the third metal electrode M3 from the first metal electrode M1 and the second metal electrode M2, so the third metal electrode M3 is electrically insulated with the first metal electrode M1 and the second metal electrode M2. In some embodiments, the insulating layer 102 includes one or more layers of low k dielectric layers, and each low k dielectric layer independently includes silicon dioxide, tetraethoxysilane, silicon nitride, borophosphosilicon dioxidete glass, the analogs thereof, or combinations thereof. In some embodiments, the preferred insulating layer 102 includes a silicon dioxide layer 102A and a silicon nitride layer 102B.

The first embodiment is continually described with reference to FIGS. 3 and 4. In the first embodiment, the semiconductor layer projection (corresponding to the double arrow 103′ shown in the figures) of the semiconductor layer 103 on the substrate 101 has a middle portion (corresponding to the double arrow 103″ shown in the figures) between the first metal electrode projection (corresponding to the double arrow M1′ shown in the figures) of the first metal electrode M1 on the substrate 101 and the second metal electrode projection (corresponding to the double arrow M2′ shown in the figures) of the second metal electrode M2 on the substrate 101, and the third metal electrode M3 has a third metal electrode projection (corresponding to the double arrow M3′ shown in the figures) on the substrate 101. In the first embodiment, the whole middle portion overlaps with the third metal electrode projection. In other words, in the direction perpendicular to the substrate 101, the projection of the third metal electrode M3 completely covers the projection of the semiconductor layer 103 between the first metal electrode M1 and the second metal electrode M2. For the purpose of a clear explanation, the relative positions and dimensions of the first metal electrode projection, the second metal electrode projection, the third metal electrode projection, the semiconductor layer projection, and the middle portion are shown in the figures with the double arrows M1′, the double arrow M2′, the double arrow M3′, the double arrow 103′, and the double arrow 103″, respectively.

One of the aspects of the first embodiment is illustrated in detail with reference to FIG. 3. In FIG. 3, the first metal electrode M1, the second metal electrode M2, and the semiconductor layer 103 are located above the third metal electrode M3 and the insulating layer 102. In detail, the third metal electrode M3 is on the substrate 101; the insulating layer 102 covers the third metal electrode M3; and the first metal electrode M1, the second metal electrode M2, and the semiconductor layer 103 are above the insulating layer 102.

Another aspect of the first embodiment is illustrated in detail with reference to FIG. 4. In FIG. 4, the first metal electrode M1, the second metal electrode M2, and the semiconductor layer 103 are located below the third metal electrode M3 and the insulating layer 102. In detail, the first metal electrode M1, the second metal electrode M2, and the semiconductor layer 103 are on the substrate 101; the insulating layer 102 is on the first metal electrode M1, the second metal electrode M2, and the semiconductor layer 103; and a third metal electrode M3 is on the insulating layer 102.

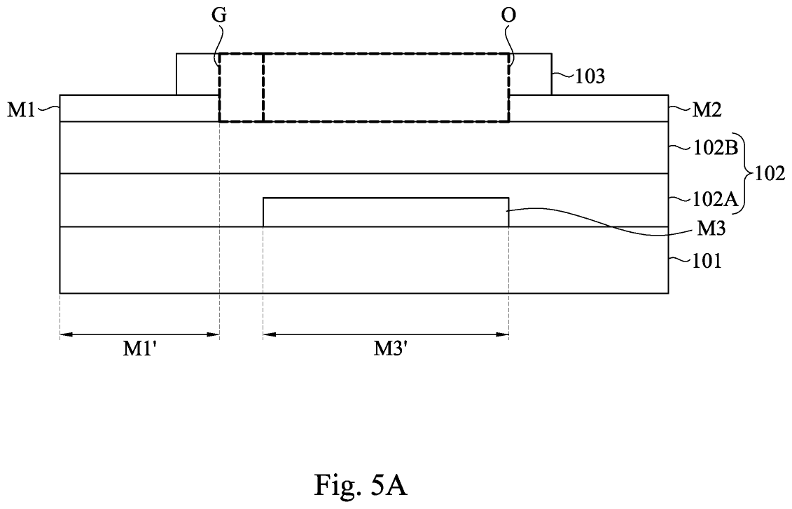

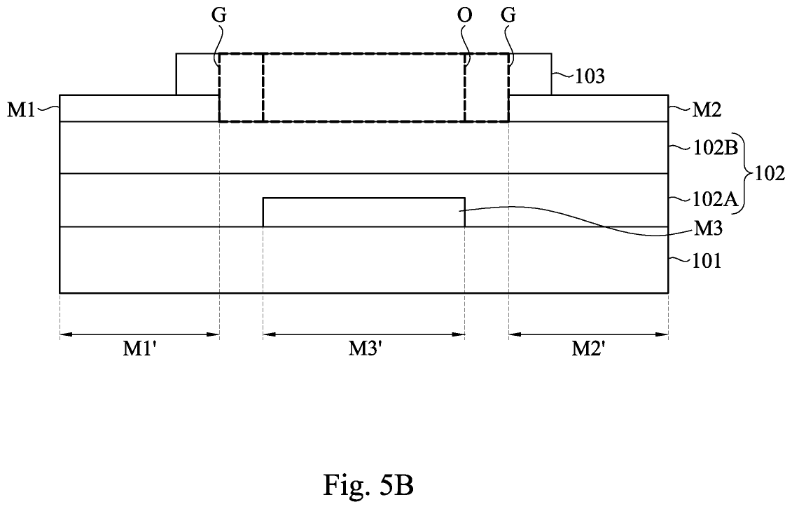

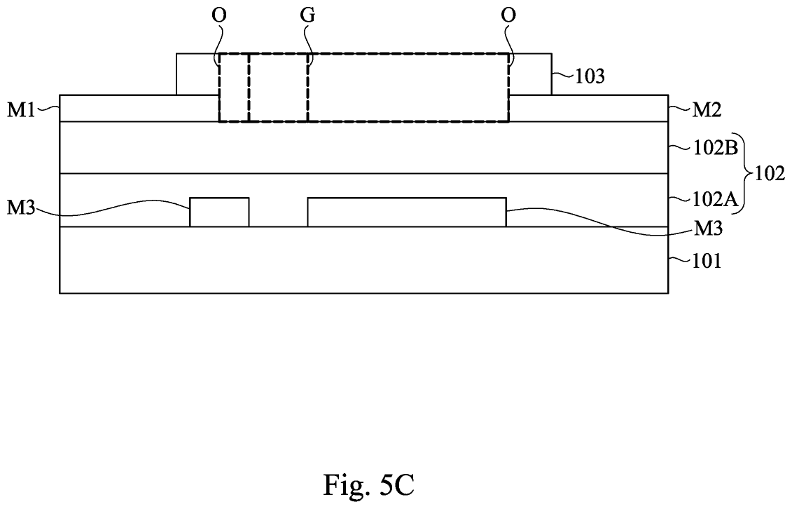

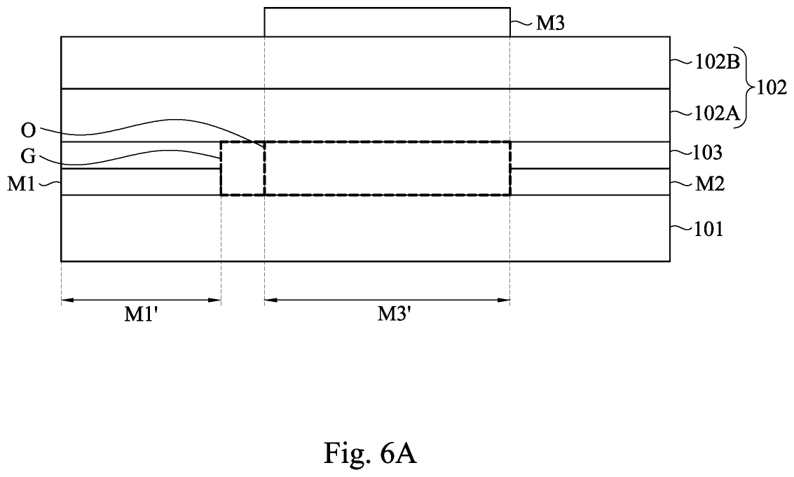

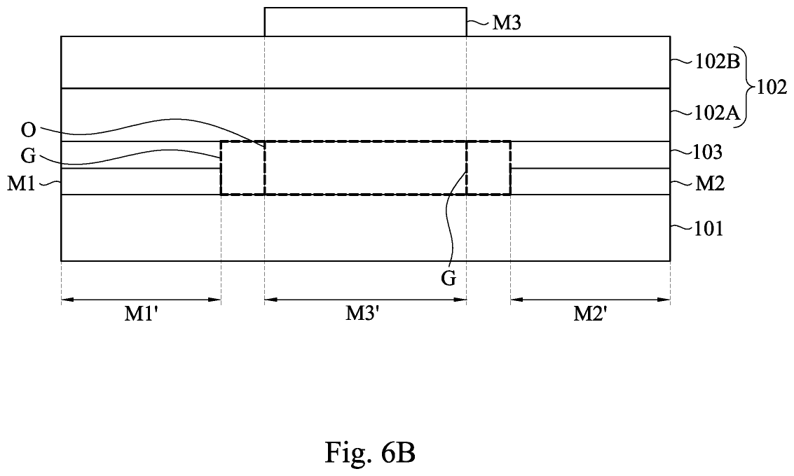

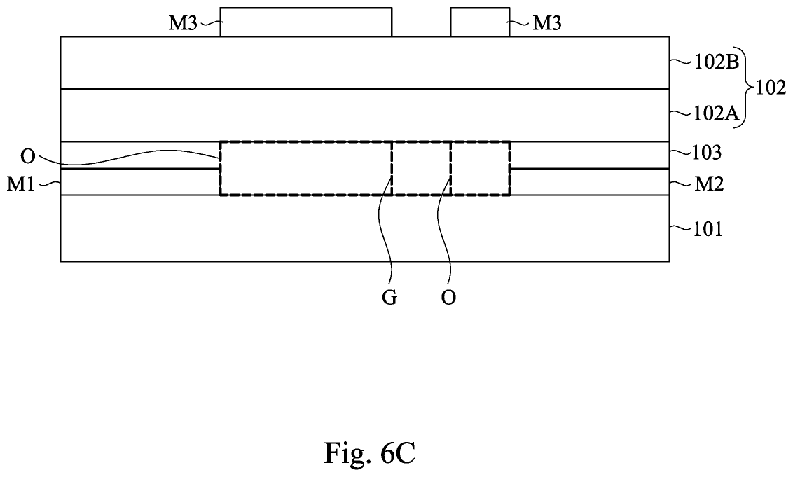

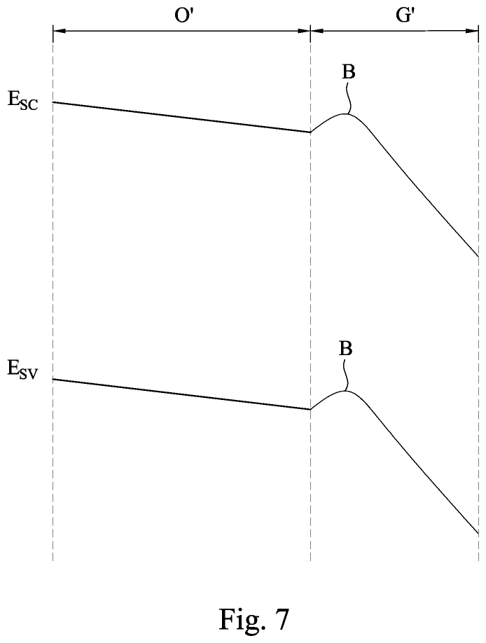

Next, a second embodiment of the device structure shown in FIG. 1 is illustrated with reference to FIGS. 5A to 6C, in which the device structure of the second embodiment further includes at least one third metal electrode M3 and an insulating layer 102 on the substrate 101. The difference between the second embodiment and the first embodiment is that, in the direction perpendicular to the substrate 101, the projection of the third metal electrode M3 in the second embodiment does not completely cover the projection of the semiconductor layer 103 between the first metal electrode M1 and the second metal electrode M2, namely a gap present between the projections (described in detail below). Therefore, in addition to having the energy barrier A between the first metal electrode M1 and the second metal electrode M2, as shown in FIG. 2, the semiconductor layer 103 of the second embodiment also has an energy barrier B corresponding to the position of the gap (refer to FIG. 7 below for more detail). In addition, in the second embodiment, the difference between FIGS. 5A to 5C and FIGS. 6A to 6C is that the third metal electrode M3 and the insulating layer 102 on the substrate 101 have different positions relative to the first metal electrode M1, the second metal electrode M2, and the semiconductor layer 103 (described in detail later). Regardless of which kind of aspect of the device structure, the device structure can sense the infrared light well as described above, which makes the method of forming the device structure include a variety of options and makes the device structure applicable to a variety of different processes.

The third metal electrode M3 of the second embodiment is continually described with reference to FIGS. 5A to 6C. The method of sensing infrared light using the device structure of the second embodiment includes applying a voltage or not applying a voltage to the third metal electrode M3. Regardless of whether a voltage is applied, the energy barrier A between the semiconductor layer 103 with the first metal electrode M1 and the second metal electrode M2 reduces by irradiating with photons, so the photocurrent increases. However, when a voltage is applied to the third metal electrode M3 in the second embodiment, the energy barrier B between the first and second portions of the semiconductor layer 103 also reduces with the irradiation of photons, thereby increasing the photocurrent (described in detail below, and refer to the method of sensing infrared light below). In addition, the third metal electrode M3 can block the light from the opposite direction of the light source that is intended to measure, thereby avoiding the sensing error caused by the light in the opposite direction of the light source to be measured and improving the accuracy of the device structure sensing the infrared light. In some embodiments, the third metal electrode M3 includes any suitable metal.

The insulating layer 102 of the second embodiment is continually described with reference to FIGS. 5A to 6C. The insulating layer 102 separates the third metal electrode M3 from the first metal electrode M1 and the second metal electrode M2, so the third metal electrode M3 is electrically insulated with the first metal electrode M1 and the second metal electrode M2. In some embodiments, the insulating layer 102 includes one or more layers of low k dielectric layers, and each low k dielectric layer independently includes silicon dioxide, tetraethoxysilane, silicon nitride, borophosphosilicon dioxidete glass, the analogs thereof, or combinations thereof. In some embodiments, the preferred insulating layer 102 includes a silicon dioxide layer 102A and a silicon nitride layer 102B.

In the second embodiment, when the at least one third metal electrode M3 is one third metal electrode M3, as shown in FIGS. 5A to 5B and 6A to 6B, the third metal electrode projection (corresponding to the double arrow M3′ in the figures) of the third metal electrode M3 on the substrate 101 is separated from the first metal electrode projection (corresponding to the double arrow M1′ in the figures) of the first metal electrode M1 on the substrate 101; separated from the second metal electrode projection (corresponding to the double arrow M2′ in the figures) of the second metal electrode M2 on the substrate 101; or separated from both the first metal electrode projection (corresponding to the double arrow M1′ in the figures) and the second metal electrode projection (corresponding to the double arrow M2s in the figures) of the first metal electrode M1 and the second metal electrode M2 on the substrate 101. In other words, in the direction perpendicular to the substrate 101, the projection of the third metal electrode M3 does not completely cover the projection of the semiconductor layer 103 between the first metal electrode M1 and the second metal electrode M2. Therefore, the semiconductor layer 103 between the first metal electrode M1 and the second metal electrode M2 includes at least one first portion G and at least one second portion O, respectively illustrated with the positions as in the dotted boxes in the figures, in which the first portion G is the portion where the projection of the semiconductor layer 103 between the first metal electrode M1 and the second metal electrode M2 does not overlap with the projection of the third metal electrode M3, and the second portion O is the portion where the projection of the semiconductor layer 103 between the first metal electrode M1 and the second metal electrode M2 overlaps with the projection of the third metal electrode M3. For the purpose of a clear explanation, the relative positions and dimensions of the first metal electrode projection, the second metal electrode projection, and the third metal electrode projection are shown in the figures with the double arrows M1′, the double arrow M2′, and the double arrow M3′, respectively. Further, although it is not additionally drawn, the position of the first metal electrode M1 and the second metal electrode M2 shown in FIGS. 5A and 6A may be switched, so the third metal electrode projection of the third metal electrode M3 on the substrate 101 can be separated from the second metal electrode projection of the second metal electrode M2 on the substrate 101.

In the second embodiment, when the at least one third metal electrode M3 includes a plurality of third metal electrodes M3, as shown in FIG. 5C and 6C, the third metal electrodes M3 are separated respectively. In other words, in the direction perpendicular to the substrate 101, the projection of the third metal electrodes M3 does not completely cover the projection of the semiconductor layer 103 between the first metal electrode M1 and the second metal electrode M2. Therefore, the semiconductor layer 103 between the first metal electrode M1 and the second metal electrode M2 includes at least one first portion G and at least one second portion O, respectively illustrated with the positions as in the dotted boxes in the figures, in which the first portion G is the portion where the projection of the semiconductor layer 103 between the first metal electrode M1 and the second metal electrode M2 does not overlap with the projection of the third metal electrodes M3, and the second portion O is the portion where the projection of the semiconductor layer 103 between the first metal electrode M1 and the second metal electrode M2 overlaps with the projection of the third metal electrodes M3. In addition, although it is not additionally drawn, the number of the third metal electrodes M3 is not limited to the number shown in the figures.

The second embodiment is continually described with reference to FIGS. 5A to 6C, and 7. FIG. 7 is a schematic diagram of the energy levels on the contact surface between the first portion G and the second portion O (the relative positions shown in the figure with the double arrow G′ and the double arrow O′) of the semiconductor layer 103 in the second embodiment. In FIG. 7, Esc is the energy level of the conduction band of the semiconductor layer 103, and Esv is the energy level of the valence band of the semiconductor layer 103. When a voltage is applied to the third metal electrode M3 (more details with reference to the method of sensing infrared light below), the energy levels of the conduction band E_{SC} and the valence band E_{SV} in the second portion O are tilted by the voltage effect, so the energy levels of the conduction band E_{SC} and the valence band E_{SV} in the first portion G form an energy barrier B at the location connecting the second portion O as the result of such tilt. The characteristics of the energy barrier B are substantially the same as the characteristics of the energy barrier A described above, so the details can refer to the above and will not be repeated herein. In other words, the photocurrent flowing through the semiconductor layer 103 increases with the increase of irradiation, and by reducing the energy barrier B with the irradiation of photons to sense the infrared light, the device structure has excellent photoelectric conversion efficiency, for example, larger than 100%external quantum efficiency, and can still generate photocurrent in the environments of weak light, for example, those where the illuminance, the intensity, or the power are substantially equal to zero. In some embodiments, the projection area of each first portion G of the semiconductor layer 103 on the substrate 101 is preferably smaller than 100 μm² and greater than 0 μm², for example, 10 μm², 20 μm², 30 μm², 40 μm², 50 μm², 60 μm², 70 μm², 80 μm², or 90 μm². If the projection area of the first portion G is too large, the resistance may increase and reduce the current. If the projection area of the first portion G is too small, the energy barrier B may not form.

The present disclosure also provides a method of sensing infrared light. The method includes the following operations. The device structure as shown in FIG. 1 is irradiated with a light source (for example, the light source including the infrared light), in which when the substrate 101 includes an opaque substrate, the light source is incident towards the side of the semiconductor layer 103 facing away from the substrate 101, and when the substrate 101 includes a transparent substrate, the light source is incident towards the side of the semiconductor layer 103 facing away from the substrate 101, the side of the semiconductor layer 103 facing the substrate 101, or a combination thereof. A first intensity of the light source is adjusted (for example, by a lens, a collimator, or any feasible method, etc.) to a second intensity to adjust a first energy barrier on the contact surface C of the semiconductor layer 103 with the first metal electrode M1 and the second metal electrode M2 to a second energy barrier, in which the second intensity is larger than the first intensity, and the second energy barrier is smaller than the first energy barrier. The first energy barrier and the second energy barrier correspond to the energy barrier A described above, except that the height of the second energy barrier is smaller than the height of the first energy barrier.

The present disclosure also provides a method of sensing infrared light. The method includes the following operations. The device structure as shown in the first embodiment of FIGS. 3 and 4 is irradiated with a light source (for example, the light source including the infrared light). A positive bias voltage or a negative bias voltage is applied to the third metal electrode M3. A first intensity of the light source is adjusted (for example, by a lens, a collimator, or any feasible method, etc.) to a second intensity to adjust a first energy barrier on the contact surface C of the semiconductor layer 103 with the first metal electrode M1 and the second metal electrode M2 to a second energy barrier, in which the second intensity is larger than the first intensity, and the second energy barrier is smaller than the first energy barrier. The first energy barrier and the second energy barrier correspond to the energy barrier A described above, except that the height of the second energy barrier is smaller than the height of the first energy barrier. In some embodiments, the preferred positive bias voltage is from +0.5 V to +25 V, for example, +0.5 V, +1 V, +5 V, +10 V, +15 V, +20 V, or +25 V, to obtain a larger photocurrent signal. In some embodiments, the preferred negative bias voltage is from −0.5 V to −5 V, for example, −0.5 V, −1 V, −2 V, −3 V, −4 V, or −5 V, to obtain a larger photocurrent signal.

The present disclosure also provides a method of sensing infrared light. The method includes the following operations. The device structure as shown in the second embodiment of FIGS. 5A to 6C is irradiated with a light source (for example, the light source including the infrared light). A positive bias voltage or a negative bias voltage is applied to the at least one third metal electrode M3. A first intensity of the light source is adjusted (for example, by a lens, a collimator, or any feasible method, etc.) to a second intensity to adjust a first energy barrier on the contact surface C of the semiconductor layer 103 with the first metal electrode M1 and the second metal electrode M2 to a second energy barrier and to adjust a third energy barrier on the contact surface between the at least one first portion G and the at least one second portion O to a fourth energy barrier, in which the second intensity is larger than the first intensity, the second energy barrier is smaller than the first energy barrier, and the fourth energy barrier is smaller than the third energy barrier. The first energy barrier and the second energy barrier correspond to the energy barrier A described above, and the third energy barrier and the fourth energy barrier correspond to the energy barrier B described above, except that the height of the second energy barrier is smaller than the height of the first energy barrier, and the height of the fourth energy barrier is smaller than the height of the third energy barrier. In some embodiments, the preferred positive bias voltage is from +0.5 V to +25 V, for example, +0.5 V, +1 V, +5 V, +10 V, +15 V, +20 V, or +25 V, to obtain a larger photocurrent signal. In some embodiments, the preferred negative bias voltage is from −0.5 V to −5 V, for example, −0.5 V, −1 V, −2 V, −3 V, −4 V, or −5 V, to obtain a larger photocurrent signal.

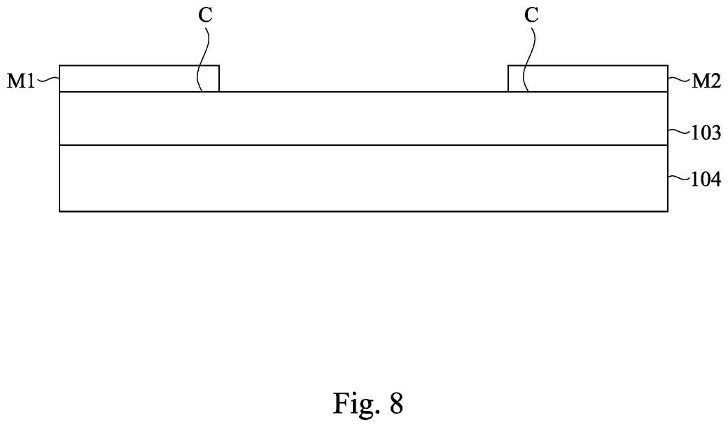

The present disclosure also provides a device structure for sensing infrared light. The device structure includes a transparent substrate, a first metal electrode and a second metal electrode on the transparent substrate, and a semiconductor layer on the transparent substrate, in which the semiconductor layer is located below the first metal electrode and the second metal electrode, the semiconductor layer is in direct contact with the first metal electrode and the second metal electrode, the first metal electrode and the second metal electrode independently include aluminum, nickel, titanium, molybdenum, chromium, gold, silver, copper, or combinations thereof, respectively, and the semiconductor layer includes InSb, InAs, HgCdTe, PbS, PbSe, Ge, Si, GaSb, InGaAs, InTlAs, InAsSb, GaAsSb, InAsP, InGaAsP, GaInSb, AlGaAsSb, AlInSb, GaAsP, AlGaAs, AlAsSb, pentacene, anthracene, tetracene, perylene, tetrahydro-2,3-naphtho[1,2-d][1,4]diazepine, benzo[c][1,2,5]thiadiazepine, poly(3-hexylthiophene), phenyl-C₆₁-butyric acid methyl ester, poly[[4,8-bis[(2-ethylhexyl)oxy]benzo[1,2-b:4,5-b′]dithiophene-2,6-diyl][3-fluoro-2-[(2-ethylhexyl) carbonyl]thieno[3,4-b]thiophenediyl]], poly[2-methoxy-5-(2′-ethylhexyloxy)-1,4-phenylenevinylene], poly(3,4-ethylenedioxythiophene) polystyrene sulfonate, poly[N-9′-heptadecanyl-2,7-carbazole-alt-5,5-(4′,7′-di-2-thienyl-2′,1′,3′-benzothiadiazole)], CuInSe₂, CuInS₂, CuGaSe₂, CuGaS₂, Cu₂ZnSnS₄, Cu₂ZnSnSe₄, Bi₂Te₃, Sb₂Te₃, ZnO, ZnTe, CdTe, CdSe, CdS, SnS, SnSe, TiO₂, CsPbBr₃, CsPbI₃, AgGaSe₂, AgGaS₂, a molybdenum disulfide two-dimensional material, a carbon nanotube, mercury telluride, or combinations thereof. The difference between the device structure (with reference to FIG. 8) and the device structure of FIG. 1 is that the substrate may be different and the position of the semiconductor layer relative to the first and second metal electrodes is different. The remaining features are substantially the same as those of the device structure shown in FIG. 1, so the detail may refer to the above and may not be repeated below. The device structure is described in detail according to some embodiments in the following.

FIG. 8 is a cross-sectional view of the device structure according to some embodiments of the present disclosure. In FIG. 8, the device structure includes a transparent substrate 104, a first metal electrode M1, a second metal electrode M2, and a semiconductor layer 103, in which the lower surface of the first metal electrode M1 and the lower surface of the second metal electrode M2 are located above the upper surface of the semiconductor layer 103. The schematic diagram of the energy levels of FIG. 2 also applies to the device structure of FIG. 8. Therefore, the device structure is described in detail with reference to FIGS. 8 and 2 in the following.

Firstly, the transparent substrate 104 is described. In some embodiments, the transparent substrate 104 is formed by a process with a temperature smaller than 600° C., for example, smaller than 550° C., smaller than 500° C., or smaller than 450° C., etc. Since the process temperature is not necessary to be too high, the process cost is reduced. In some embodiments, the transparent substrate 104 includes quartz (or glass), sapphire, gallium nitride, or combinations thereof. In some embodiments, the transparent substrate 104 further includes an active component (e.g., a diode or a transistor, etc.), a passive component (e.g., a resistor, a capacitor, or an inductor, etc.), a conductive structure (e.g., a wire, etc.), or combinations thereof.

The characteristics, for example, the energy gap, etc., of the semiconductor layer 103 in the device structure are substantially the same as those described above, so the detail is not repeated herein.

The characteristics, for example, the relative positions between the first metal electrode M1 and the second metal electrode M2 in the device structure, are substantially the same as those described above, so the detail is not repeated herein.

Next, when the semiconductor layer 103 of FIG. 8 is in direct contact with the first metal electrode M1 and the second metal electrode M2, the contact surface C of the semiconductor layer 103 between the first metal electrode M1 and the second metal electrode M2 is illustrated with the energy levels with reference to FIG. 2. The characteristics of the energy levels (for example, the energy barrier A, etc.) are substantially the same as those described above, so the detail is not repeated herein. In other words, the photocurrent between the semiconductor layer 103 with the first metal electrode M1 and the second metal electrode M2 increases as the irradiation of the photon increases, and by reducing the energy barrier A with the irradiation of photons to sense the infrared light, the device structure has excellent photoelectric conversion efficiency, for example, larger than 100% external quantum efficiency, and can still generate photocurrent in the environments of weak light, for example, those where the illuminance, the intensity, or the power are substantially equal to zero.

The device structure is continually described. In some embodiments, the device structure may be repeatedly arranged on the plane parallel to the transparent substrate 104 to form a repeating array as a matrix. In some embodiments, a collimator (not drawn in the figures), a lens (not drawn in the figures), or a combination thereof may be disposed on the device structure to improve the accuracy of sensing infrared light or to focus the incident light on the device structure to enhance the sensing intensity.

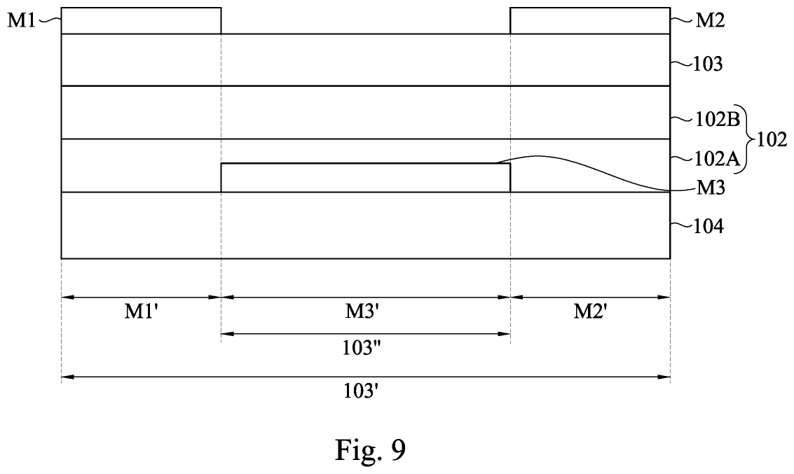

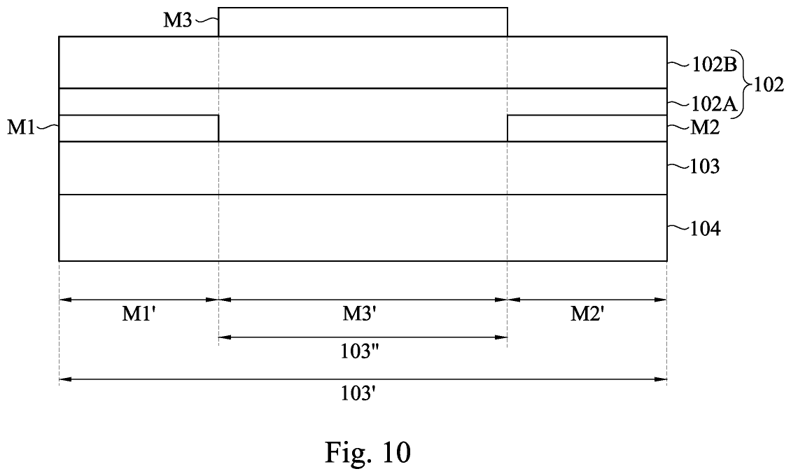

Next, a third embodiment of the device structure shown in FIG. 8 is described with reference to FIGS. 9 and 10, in which the device structure of the third embodiment further includes a third metal electrode M3 and an insulating layer 102 on the transparent substrate 104. The difference between the device structure of the third embodiment and the device structure of the first embodiment shown in FIGS. 3 and 4 is that the substrate may be different and the position of the semiconductor layer 103 relative to the first metal electrode M1 and the second metal electrode M2 is different. The remaining features are substantially the same as those of the device structure of the first embodiment, so the detail may refer to the above and may not be repeated below. Further, the difference between FIG. 9 and FIG. 10 in the third embodiment is also the same as the difference between FIG. 3 and FIG. 4 in the first embodiment, in which the difference is that the positions of the third metal electrode M3 and the insulating layer 102 relative to the first metal electrode M1, the second metal electrode M2, and the semiconductor layer 103 are different on the substrate 101/transparent substrate 104. Regardless of which kind of aspect of the device structure, the device structure can sense the infrared light well as described above, which makes the method of forming the device structure include a variety of options and makes the device structure applicable to a variety of different processes.

The descriptions of the third metal electrode M3 in the third embodiment shown in FIGS. 9 and 10, including the material of the third metal electrode M3, may or may not applying a voltage to the third metal electrode M3 when sensing the infrared light, the third metal electrode M3 blocking the light from the opposite direction of the light source intended to be measured, and so on, are substantially the same as those described in the first embodiment and are not repeated herein.

The descriptions of the insulating layer 102 in the third embodiment shown in FIGS. 9 and 10, including the material of the insulating layer 102, and so on, are substantially the same as those described in the first embodiment and are not repeated herein.

The third embodiment is continually described with reference to FIGS. 9 and 10. In the third embodiment, the semiconductor layer projection (corresponding to the double arrow 103′ in the figures) of the semiconductor layer 103 on the transparent substrate 104 has a middle portion (corresponding to the double arrow 103″ in the figures) between the first metal electrode projection (corresponding to the double arrow M1′ in the figures) of the first metal electrode M1 on the transparent substrate 104 and the second metal electrode projection (corresponding to the double arrow M2′ in the figures) of the second metal electrode M2 on the transparent substrate 104, and the third metal electrode M3 has the third metal electrode projection (corresponding to the double arrow M3′ in the figures) on the transparent substrate 104. Substantially the same as the first embodiment, in the third embodiment, the whole middle portion also overlaps with the third metal electrode projection. In other words, in the direction perpendicular to the transparent substrate 104, the projection of the third metal electrode M3 completely covers the projection of the semiconductor layer 103 between the first metal electrode M1 and the second metal electrode M2. For the purpose of a clear explanation, the relative positions and dimensions of the first metal electrode projection, the second metal electrode projection, the third metal electrode projection, the semiconductor layer projection, and the middle portion are shown in the figures with the double arrows M1′, the double arrow M2′, the double arrow M3′, the double arrow 103′, and the double arrow 103″, respectively.

One aspect of the third embodiment is illustrated with reference to FIG. 9. In FIG. 9, the first metal electrode M1, the second metal electrode M2, and the semiconductor layer 103 are located above the third metal electrode M3 and the insulating layer 102. In detail, the third metal electrode M3 is on the transparent substrate 104; the insulating layer 102 covers the third metal electrode M3; and the first metal electrode M1, the second metal electrode M2, and the semiconductor layer 103 is on the insulating layer 102.

Another aspect of the third embodiment is illustrated with referring to FIG. 10. In FIG. 10, the first metal electrode M1, the second metal electrode M2, and the semiconductor layer 103 are located below the third metal electrode M3 and the insulating layer 102. In detail, the first metal electrode M1, the second metal electrode M2, and the semiconductor layer 103 are on the transparent substrate 104; the insulating layer 102 is on the first metal electrode M1, the second metal electrode M2, and the semiconductor layer 103; and the third metal electrode M3 is on the insulating layer 102.

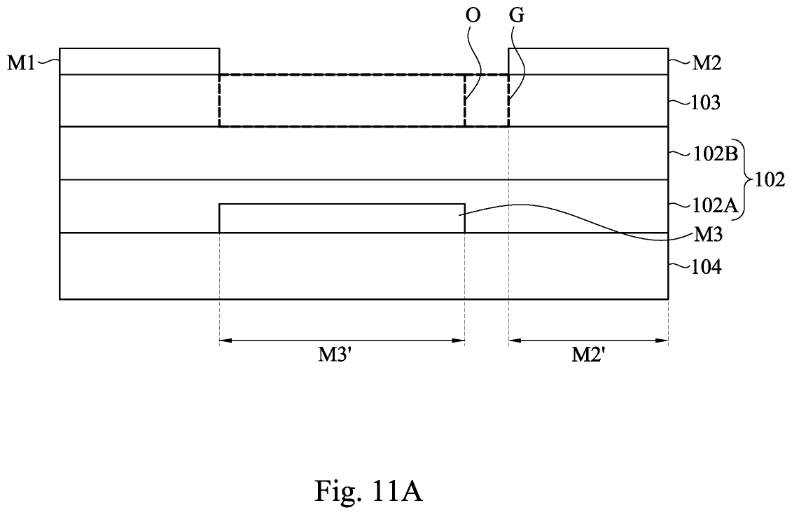

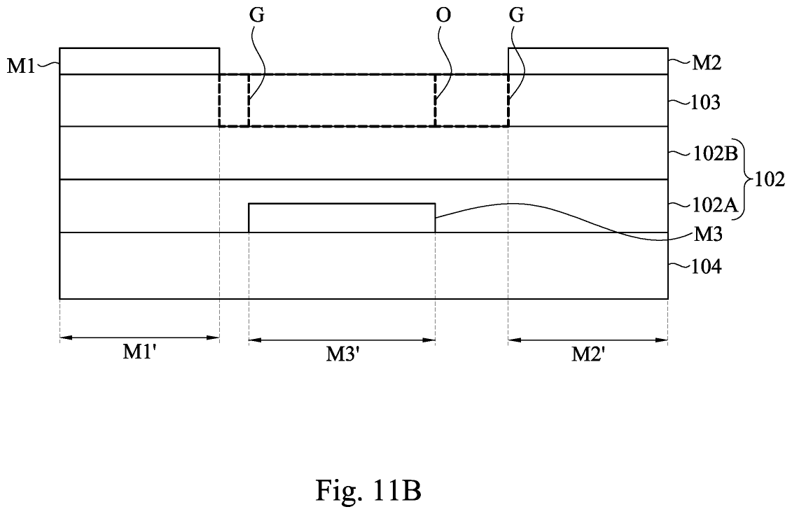

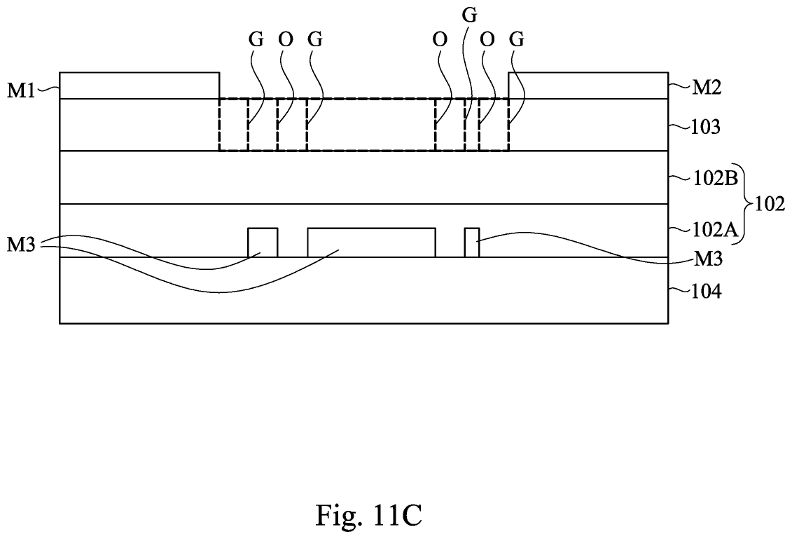

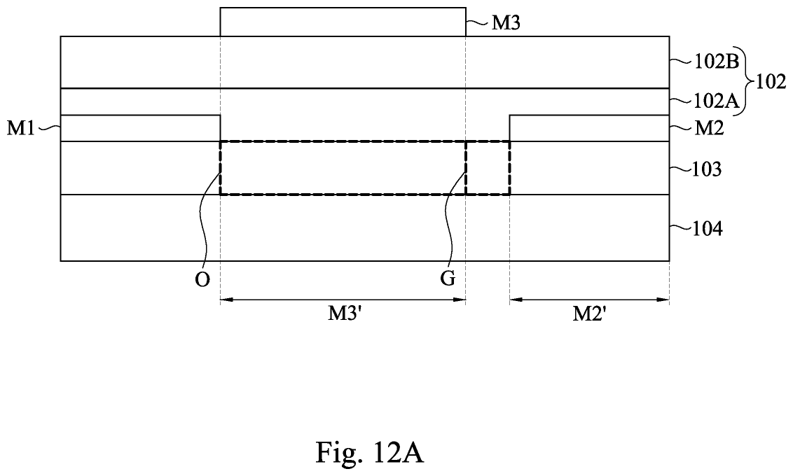

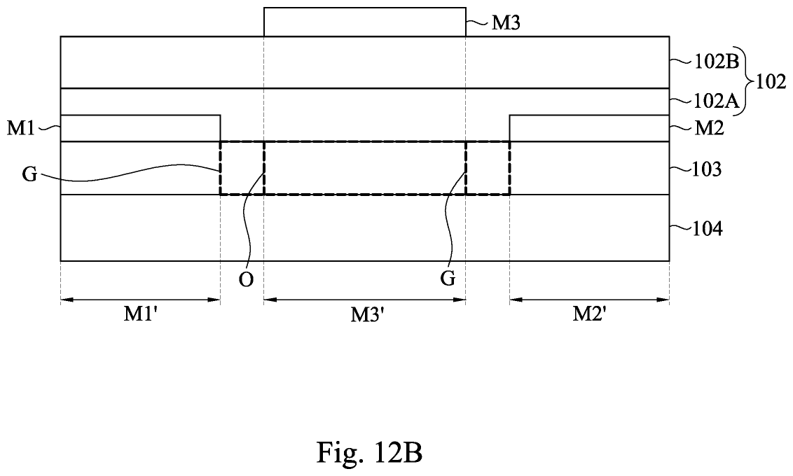

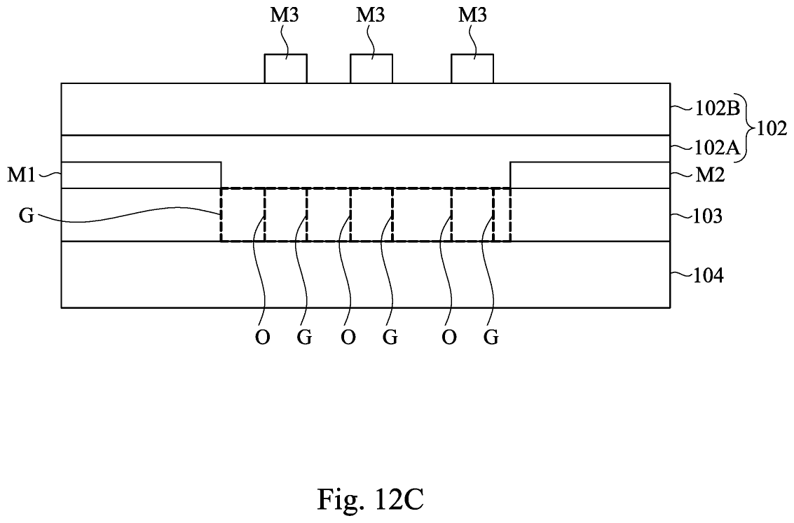

Further, a fourth embodiment of the device structure shown in FIG. 8 is illustrated with reference to FIGS. 11A to 12C, in which the device structure of the fourth embodiment further includes at least one third metal electrode M3 and an insulating layer 102 on the transparent substrate 104. The difference between the device structure of the fourth embodiment and the device structure of the second embodiment shown in FIGS. 5A to 6C is that the substrate may be different and the position of the semiconductor layer 103 relative to the first metal electrode M1 and the second metal electrode M2 are different. The remaining features are substantially the same as those of the device structure of the second embodiment, so the detail may refer to the above and may not be repeated below. In addition, the difference between the fourth embodiment and the second embodiment is also the same as the difference between the second embodiment and the first embodiment, which is that, in a direction perpendicular to the transparent substrate 104, the projection of the third metal electrode M3 of the fourth embodiment does not completely cover the projection of the semiconductor layer 103 between the first metal electrode M1 and the second metal electrode M2, thereby having a gap between the projections. Therefore, in addition to the energy barrier A between the semiconductor layer 103 with the first metal electrode M1 and the second metal electrode M2, as shown in FIG. 2, the semiconductor layer 103 of the fourth embodiment also has an energy barrier B corresponding to the positions of the gap (more detail with reference to FIG. 7). Further, the difference between FIGS. 11A to 11C and FIGS. 12A to 12C in the fourth embodiment is also the same as the difference between FIGS. 5A to 5C and FIGS. 6A to 6C in the second embodiment, in which the difference is that the positions of the third metal electrode M3 and the insulating layer 102 relative to the first metal electrode M1, the second metal electrode M2, and the semiconductor layer 103 are different on the substrate 101/transparent substrate 104. Regardless of which kind of aspect of the device structure, the device structure can sense the infrared light well as described above, which makes the method of forming the device structure include a variety of options and makes the device structure applicable to a variety of different processes.

The descriptions of the third metal electrode M3 in the fourth embodiment shown in FIGS. 11A to 12C, including the material of the third metal electrode M3, may or may not applying a voltage to the third metal electrode M3 when sensing the infrared light (however, applying the voltage increases the photocurrent as the energy barrier B between the first and second portions of the semiconductor layer 103 decreases upon irradiating with light), the third metal electrode M3 blocking the light from the opposite direction of the light source that is intended to be measured, and so on, are substantially the same as those described in the second embodiment and are not repeated herein.

The descriptions of the insulating layer 102 in the fourth embodiment shown in FIGS. 11A to 12C, including the material of the insulating layer 102, and so on, are substantially the same as those described in the second embodiment and are not repeated herein.

Substantially the same as the second embodiment, in the fourth embodiment, when the at least one third metal electrode M3 is one third metal electrode M3, as shown in FIGS. 11A to 11B and FIGS. 12A to 12B, the third metal electrode projection (corresponding to the double arrow M3′ in the figures) of the third metal electrode M3 on the transparent substrate 104 is separated from the first metal electrode projection (corresponding to the double arrow M1′ in the figures) of the first metal electrode M1 on the transparent substrate 104; separated from the second metal electrode projection (corresponding to the double arrow M2′ in the figures) of the second metal electrode M2 on the transparent substrate 104; or separated from both the first metal electrode projection (corresponding to the double arrow M1′ in the figures) of the first metal electrode M1 and the second metal electrode projection (corresponding to the double arrow M2′ in the figures) of the second metal electrode M2 on the transparent substrate 104. In other words, in the direction perpendicular to the transparent substrate 104, the projection of the third metal electrode M3 does not completely cover the projection of the semiconductor layer 103 between the first metal electrode M1 and the second metal electrode M2. Therefore, the semiconductor layer 103 between the first metal electrode M1 and the second metal electrode M2 includes at least one first portion G and at least one second portion O, respectively illustrated with the positions as in the dotted boxes in the figures, in which the first portion G is the portion of the semiconductor layer 103 where its projection that is between the first metal electrode M1 and the second metal electrode M2 does not overlap with the projection of the third metal electrode M3, and the second portion O is the portion of the semiconductor layer 103 where its projection that is between the first metal electrode M1 and the second metal electrode M2 overlaps with the projection of the third metal electrode M3. For the purpose of a clear explanation, the relative positions and dimensions of the first metal electrode projection, the second metal electrode projection, and the third metal electrode projection are shown in the figures with the double arrows M1′, the double arrow M2′, and the double arrow M3′, respectively. Further, although it is not additionally drawn, the position of the first metal electrode M1 and the second metal electrode M2 shown in FIGS. 11A and 12A may be switched, so the third metal electrode projection of the third metal electrode M3 on the transparent substrate 104 can be separated from the first metal electrode projection of the first metal electrode M1 on the transparent substrate 104.

Substantially the same as the second embodiment, in the fourth embodiment, when the at least one third metal electrode M3 includes a plurality of third metal electrodes M3, as shown in FIGS. 11C and 12C, these third metal electrodes M3 are separated from each other. In other words, in the direction perpendicular to the transparent substrate 104, the projection of the third metal electrodes M3 does not completely cover the projection of the semiconductor layer 103 between the first metal electrode M1 and the second metal electrode M2. Therefore, the semiconductor layer 103 that is between the first metal electrode M1 and the second metal electrode M2 includes at least one first portion G and at least one second portion O, respectively illustrated with the positions as in the dotted boxes in the figures, in which the first portion G is the portion where the projection of the semiconductor layer 103 between the first metal electrode M1 and the second metal electrode M2 does not overlap with the projection of the third metal electrodes M3, and the second portion O is the portion where the projection of the semiconductor layer 103 between the first metal electrode M1 and the second metal electrode M2 overlaps with the projection of the third metal electrodes M3. In addition, although it is not additionally drawn, the number of the third metal electrodes M3 is not limited to the number shown in the figures.

The fourth embodiment is continually described with reference to FIGS. 11A to 12C and 7. FIG. 7 is also a schematic diagram of the energy levels on the contact surface between the first portion G and the second portion O of the semiconductor layer 103 (with reference to the detail above, which is not repeated herein). Therefore, when a voltage is applied to the third metal electrode M3 of the fourth embodiment (with reference to the method of sensing infrared light described below), the energy levels of the conduction band Esc and the valence band E_{SV} in the first portion G also form an energy barrier B at the position connecting the second portion O. Therefore, the photocurrent flowing through the semiconductor layer 103 increases with the increase of irradiation, and by reducing the energy barrier B with the irradiation of photons to sense the infrared light, the device structure has excellent photoelectric conversion efficiency, for example, larger than 100% external quantum efficiency, and can still generate photocurrent in the environments of weak light, for example, those where the illuminance, the intensity, or the power are substantially equal to zero. In some embodiments, the projection area of each first portion G of the semiconductor layer 103 on the transparent substrate 104 is preferably smaller than 100 μm² and greater than 0 μm², for example, 10 μm², 20 μm², 30 μm², 40 μm², 50 μm², 60 μm², 70 μm², 80 μm², or 90 μm². If the projection area of the first portion G is too large, the resistance may increase and reduce the current. If the projection area of the first portion G is too small, the energy barrier B may not form.

The present disclosure also provides a method of sensing infrared light. The method includes the following operations. The device structure as shown in FIG. 8 is irradiated with a light source (for example, the light source including the infrared light), in which the light source is incident towards the side of the semiconductor layer 103 facing the transparent substrate 104. A first intensity of the light source is adjusted (for example, by a lens, a collimator, or any feasible method, etc.) to a second intensity to adjust a first energy barrier on the contact surface C of the semiconductor layer 103 with the first metal electrode M1 and the second metal electrode M2 to a second energy barrier, in which the second intensity is larger than the first intensity, and the second energy barrier is smaller than the first energy barrier. The first energy barrier and the second energy barrier correspond to the energy barrier A described above, except that the height of the second energy barrier is smaller than the height of the first energy barrier.

The present disclosure also provides a method of sensing infrared light. The method includes the following operations. The device structure as shown in the third embodiment of FIGS. 9 and 10 is irradiated with a light source (for example, the light source including the infrared light). A positive bias voltage or a negative bias voltage is applied to the third metal electrode M3. A first intensity of the light source is adjusted (for example, by a lens, a collimator, or any feasible method, etc.) to a second intensity to adjust a first energy barrier on the contact surface C of the semiconductor layer 103 with the first metal electrode M1 and the second metal electrode M2 to a second energy barrier, in which the second intensity is larger than the first intensity, and the second energy barrier is smaller than the first energy barrier. The first energy barrier and the second energy barrier correspond to the energy barrier A described above, except that the height of the second energy barrier is smaller than the height of the first energy barrier. In some embodiments, the preferred positive bias voltage is from +0.5 V to +25 V, for example, +0.5 V, +1 V, +5 V, +10 V, +15 V, +20 V, or +25 V, to obtain a larger photocurrent signal. In some embodiments, the preferred negative bias voltage is from −0.5 V to −5 V, for example, −0.5 V, −1 V, −2 V, −3 V, −4 V, or −5 V, to obtain a larger photocurrent signal.

The present disclosure also provides a method of sensing infrared light. The method includes the following operations. The device structure as shown in the fourth embodiment of FIGS. 11A to 12C is irradiated with a light source (for example, the light source including the infrared light). A positive bias voltage or a negative bias voltage is applied to the at least one third metal electrode M3. A first intensity of the light source is adjusted (for example, by a lens, a collimator, or any feasible method, etc.) to a second intensity to adjust a first energy barrier on the contact surface C of the semiconductor layer 103 with the first metal electrode M1 and the second metal electrode M2 to a second energy barrier and to adjust a third energy barrier on the contact surface between the at least one first portion G and the at least one second portion O to a fourth energy barrier, in which the second intensity is larger than the first intensity, the second energy barrier is smaller than the first energy barrier, and the fourth energy barrier is smaller than the third energy barrier. The first energy barrier and the second energy barrier correspond to the energy barrier A described above, and the third energy barrier and the fourth energy barrier correspond to the energy barrier B described above, except that the height of the second energy barrier is smaller than the height of the first energy barrier, and the height of the fourth energy barrier is smaller than the height of the third energy barrier. In some embodiments, the preferred positive bias voltage is from +0.5 V to +25 V, for example, +0.5 V, +1 V, +5 V, +10 V, +15 V, +20 V, or +25 V, to obtain a larger photocurrent signal. In some embodiments, the preferred negative bias voltage is from −0.5 V to −5 V, for example, −0.5 V, −1 V, −2 V, −3 V, −4 V, or −5 V, to obtain a larger photocurrent signal.

Next, only some embodiments are provided to illustrate the device structure of the present disclosure. As long as the device structure has the characteristics described above, it will have the advantageous effects as shown below. Therefore, the scope of the present disclosure intended to cover should not be regarded as limited by the details of the embodiments.

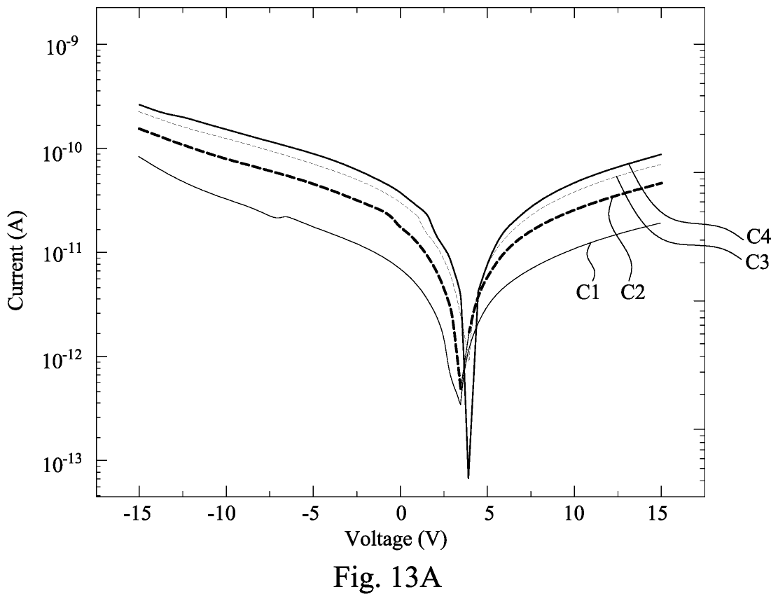

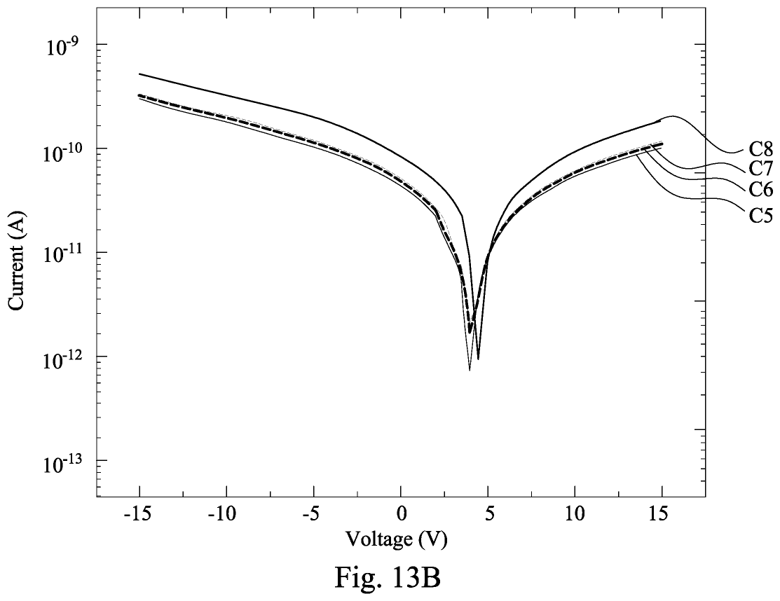

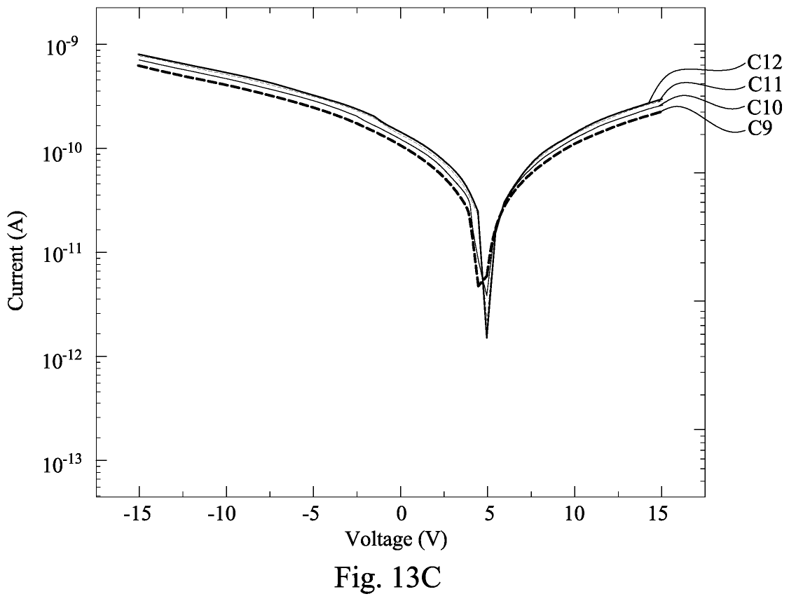

In Embodiment 1, with reference to FIGS. 13A to 13C, the device structure includes the structure as shown in the first embodiment (with reference to FIGS. 3 to 4) or the third embodiment (with reference to FIGS. 9 to 10). The first metal electrode M1 and the second metal electrode M2 each include molybdenum. The semiconductor layer 103 includes lead(II) sulfide quantum dots. In FIGS. 13A to 13C, the curve C1, the curve C2, the curve C3, the curve C4, the curve C5, the curve C6, the curve C7, the curve C8, the curve C9, the curve C10, the curve C11, and the curve C12 are the current changing with the voltage when the infrared light intensities are respectively corresponding to ˜0 W/m², 0.01 W/m², 0.03 W/m², 0.05 W/m², 0.07 W/m², 0.09 W/m², 0.1 W/m², 0.3 W/m², 0.5 W/m², 0.7 W/m², 0.9 W/m², and 1 W/m². Regardless of whether a positive bias voltage, a negative bias voltage, or a zero bias voltage is applied to the third metal electrode M3, the current of the device structure increases with the intensity of the infrared light, and the current can be sensed to also increase with the intensity of the infrared light even when the intensity is very small.

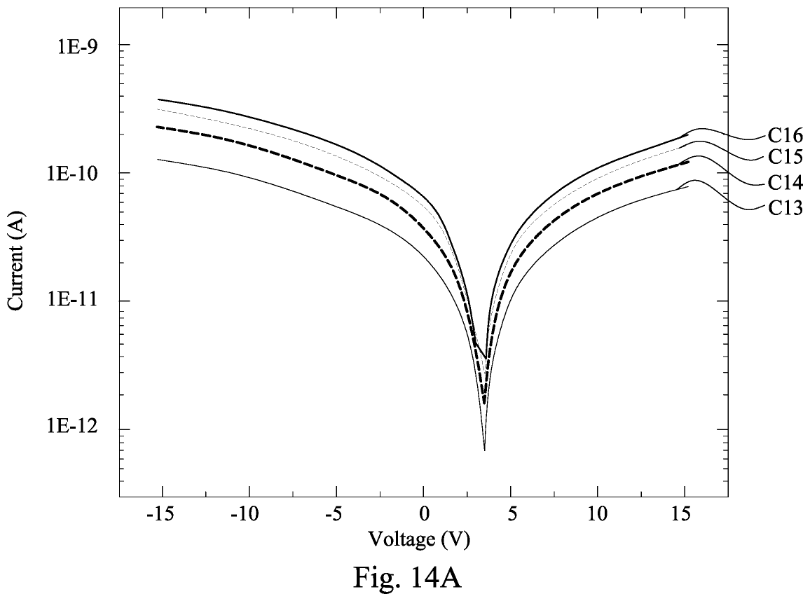

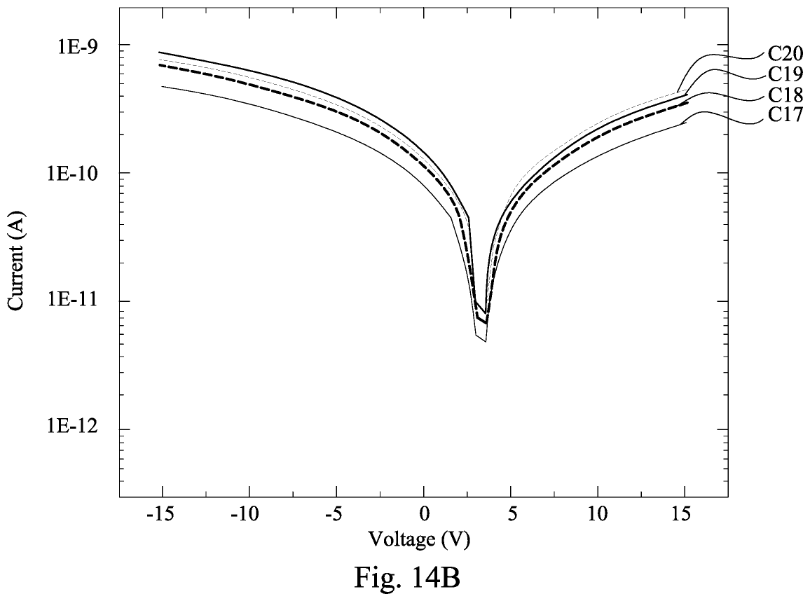

In Example 2, with reference to FIGS. 14A to 14B, the device structure includes the structure as shown in the second embodiment (with reference to FIGS. 5A to 6C) or the fourth embodiment (FIGS. 11A to 12C). The first metal electrode M1 and the second metal electrode M2 each include molybdenum. The semiconductor layer 103 includes lead(II) sulfide quantum dots. In FIG. 14A and FIG. 14B, the curve C13, the curve C14, the curve C15, the curve C16, the curve C17, the curve C18, the curve C19, and the curve C20 are the current changing with the voltage when the intensities of the infrared light are respectively corresponding to ˜0 W/m², 0.01 W/m², 0.03 W/m², 0.05 W/m², 0.1 W/m², 0.3 W/m², 0.5 W/m², and 0.7 W/m². Regardless of whether a positive bias voltage, a negative bias voltage, or a zero bias voltage is applied to the third metal electrode M3, the current of the device structure increases with the intensity of the infrared light, and the current can be sensed to also increase with the intensity of the infrared light even when the intensity is very small.

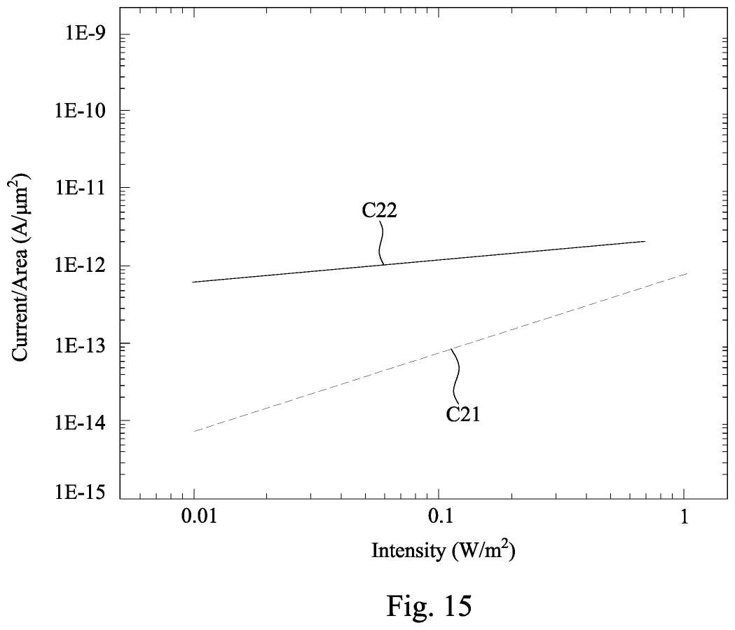

In FIG. 15, the curve C21 corresponds to the change of the current per unit area with the intensity of the infrared light when the device structure has 100% external quantum efficiency, and the curve C22 corresponds to the change of the current per unit area with the intensity of the infrared light in Embodiment 2. By reducing the energy barriers by increasing the irradiation, the device structure of the present disclosure has an external quantum efficiency larger than 100%.

Although it is not additionally drawn in the present disclosure for the purpose of simplifying the description, the different combinations of the semiconductor layer 103, the first metal electrode M1, and the second metal electrode M2, as shown in the present disclosure, all obtain the advantageous effects as shown in the embodiments above, except for that the wavelength of absorbing the infrared light may be different. For example, when the semiconductor layer 103 includes InSb, InAs, HgCdTe, PbS, PbSe, Ge, Si, GaSb, InGaAs, InTlAs, InAsSb, GaAsSb, InAsP, InGaAsP, GaInSb, AlGaAsSb, AlInSb, GaAsP, AlGaAs, AlAsSb, or the organic material (e.g., P3HT, PCBM, PTB7, MEH-PPV, PEDOT: PSS, or PCDTBT, etc.), the device structure senses the energy that includes the wavelength of the infrared light at about 0.17 eV, 0.36 eV, 0.1 eV to 0.8 eV, 0.37 eV, 0.27 eV, 0.67 eV, 1.12 eV, 0.73 eV, 0.35 eV to 1.42 eV, 0.15 eV to 0.5 eV, 0.17 eV to 0.73 eV, 0.36 eV to 1.43 eV, 0.36 eV to 1.35 eV, 0.35 eV to 1.42 eV, 0.17 eV to 0.73 eV, 0.73 eV to 2.16 eV, 0.17 eV to 2.39 eV, 1.42 eV to 1.93 eV, 1.42 eV to 2.16 eV, 0.73 eV to 2.39 eV, or 1 eV to 3 eV, respectively.

The device structure of the present disclosure can sense infrared light well. For example, the photocurrent increases with the increasing irradiation of illuminance, intensity, or power of light. Also, the device structure can sense infrared light in environments of weak light. The device structure also has good photoelectric conversion efficiency, for example, the external quantum efficiency larger than 100%. In addition, the device structure includes a variety of aspects for the application of a variety of different semiconductor processes.

The present disclosure is described in considerable detail by some embodiments. However, other embodiments may be feasible. Therefore, the scope and the spirit of the attached claims intended to cover should not be limited by the description of the embodiments provided in the present disclosure.

For one skilled in the art, the present disclosure can be modified and changed without deviating from the scope and the spirit of the present disclosure. As long as the modifications and the changes fall within the scope and the spirit of the attached claims, these modifications and changes are covered by the present disclosure.

What is claimed is:

1. A device structure for sensing infrared light, comprising:
a substrate;
a first metal electrode and a second metal electrode on the substrate; and
a semiconductor layer on the substrate, wherein the semiconductor layer is located between and above the first metal electrode and the second metal electrode, the semiconductor layer is in direct contact with the first metal electrode and the second metal electrode, the first metal electrode and the second metal electrode independently comprise aluminum, nickel, titanium, molybdenum, chromium, gold, silver, copper, or combinations thereof, respectively, and the semiconductor layer comprises InSb, InAs, HgCdTe, PbS, PbSe, Ge, Si, GaSb, InGaAs, InTlAs, InAsSb, GaAsSb, InAsP, InGaAsP, GaInSb, AlGaAsSb, AlInSb, GaAsP, AlGaAs, AlAsSb, pentacene, anthracene, tetracene, perylene, tetrahydro-2,3-naphtho[1,2-d][1,4]diazepine, benzo[c][1,2,5]thiadiazepine, poly(3-hexylthiophene), phenyl-C₆₁-butyric acid methyl ester, poly[[4,8-bis[(2-ethylhexyl)oxy]benzo[1,2-b:4,5-b′]dithiophene-2,6-diyl][3-fluoro-2-[(2-ethylhexyl) carbonyl]thieno[3,4-b]thiophenediyl]], poly[2-methoxy-5-(2′-ethylhexyloxy)-1,4-phenylenevinylene], poly(3,4-ethylenedioxythiophene) polystyrene sulfonate, poly[N-9′-heptadecanyl-2,7-carbazole-alt-5,5-(4′,7′-di-2-thienyl-2′,1′,3′-benzothiadiazole)], CuInSe₂, CuInS₂, CuGaSe₂, CuGaS₂, Cu₂ZnSnS₄, Cu₂ZnSnSe₄, Bi₂Te₃, Sb₂Te₃, ZnO, ZnTe, CdTe, CdSe, CdS, SnS, SnSe, TiO₂, CsPbBr₃, CsPbI₃, AgGaSe₂, AgGaS₂, a molybdenum disulfide two-dimensional material, a carbon nanotube, mercury telluride, or combinations thereof.

2. The device structure of claim 1, wherein the substrate is formed by a process with a process temperature smaller than 600° C., and the substrate comprises quartz, plastic, stainless steel, crystalline silicon, sapphire, gallium nitride, or combinations thereof.

3. The device structure of claim 1, further comprising:
a third metal electrode on the substrate; and
an insulating layer on the substrate, wherein the third metal electrode is separated from the first metal electrode and the second metal electrode by the insulating layer, a semiconductor layer projection of the semiconductor layer on the substrate has a middle portion between a first metal electrode projection of the first metal electrode on the substrate and a second metal electrode projection of the second metal electrode on the substrate, the third metal electrode has a third metal electrode projection on the substrate, and all the middle portion overlaps with the third metal electrode projection.

4. The device structure of claim 1, further comprising:
at least one third metal electrode on the substrate, wherein the semiconductor layer has a middle portion between the first metal electrode and the second metal electrode, the middle portion comprises at least one first portion and at least one second portion, a projection of the at least one first portion on the substrate does not overlap with a third metal electrode projection of the at least one third metal electrode on the substrate, and a projection of the at least one second portion on the substrate overlaps with the third metal electrode projection; and
an insulating layer on the substrate, wherein the at least one third metal electrode is separated from the first metal electrode and the second metal electrode by the insulating layer.

5. The device structure of claim 4, wherein a projection area of each one of the at least one first portion on the substrate is smaller than 100 μm².

6. A method of sensing infrared light, comprising:
irradiating the device structure of claim 1 with a light source, wherein when the substrate comprises an opaque substrate, the light source is incident towards a side of the semiconductor layer facing away from the substrate, and when the substrate comprises a transparent substrate, the light source is incident towards the side of the semiconductor layer facing away from the substrate, a side of the semiconductor layer facing the substrate, or a combination thereof; and
adjusting a first intensity of the light source to a second intensity to adjust a first energy barrier on a contact surface of the semiconductor layer with the first metal electrode and the second metal electrode to a second energy barrier, wherein the second intensity is larger than the first intensity, and the second energy barrier is smaller than the first energy barrier.

7. A method of sensing infrared light, comprising:
irradiating the device structure of claim 3 with a light source;
applying a positive bias voltage or a negative bias voltage to the third metal electrode; and
adjusting a first intensity of the light source to a second intensity to adjust a first energy barrier on a contact surface of the semiconductor layer with the first metal electrode and the second metal electrode to a second energy barrier, wherein the second intensity is larger than the first intensity, and the second energy barrier is smaller than the first energy barrier.

8. The method of claim 7, wherein the positive bias voltage is from +0.5 V to +25 V, and the negative bias voltage is from −0.5 V to −5 V.

9. A method of sensing infrared light, comprising:
irradiating the device structure of claims 4 with a light source;
applying a positive bias voltage or a negative bias voltage to the at least one third metal electrode; and
adjusting a first intensity of the light source to a second intensity to adjust a first energy barrier on a contact surface of the semiconductor layer with the first metal electrode and the second metal electrode to a second energy barrier and to adjust a third energy barrier on a contact surface between the at least one first portion and the at least one second portion to a fourth energy barrier, wherein the second intensity is larger than the first intensity, the second energy barrier is smaller than the first energy barrier, and the fourth energy barrier is smaller than the third energy barrier.

10. A device structure for sensing infrared light, comprising:
a transparent substrate;
a first metal electrode and a second metal electrode on the transparent substrate; and
a semiconductor layer on the transparent substrate, wherein the semiconductor layer is located below the first metal electrode and the second metal electrode, the semiconductor layer is in direct contact with the first metal electrode and the second metal electrode, the first metal electrode and the second metal electrode independently comprise aluminum, nickel, titanium, molybdenum, chromium, gold, silver, copper, or combinations thereof, respectively, and the semiconductor layer comprises InSb, InAs, HgCdTe, PbS, PbSe, Ge, Si, GaSb, InGaAs, InTlAs, InAsSb, GaAsSb, InAsP, InGaAsP, GaInSb, AlGaAsSb, AlInSb, GaAsP, AlGaAs, AlAsSb, pentacene, anthracene, tetracene, perylene, tetrahydro-2,3-naphtho[1,2-d][1,4]diazepine, benzo[c][1,2,5]thiadiazepine, poly(3-hexylthiophene), phenyl-C₆₁-butyric acid methyl ester, poly[[4,8-bis[(2-ethylhexyl)oxy]benzo[1,2-b:4,5-b′]dithiophene-2,6-diyl][3-fluoro-2-[(2-ethylhexyl) carbonyl]thieno[3,4-b]thiophenediyl]], poly[2-methoxy-5-(2′-ethylhexyloxy)-1,4-phenylenevinylene], poly(3,4-ethylenedioxythiophene) polystyrene sulfonate, poly[N-9′-heptadecanyl-2,7-carbazole-alt-5,5-(4′,7′-di-2-thienyl-2′,1′,3′-benzothiadiazole)], CuInSe₂, CuInS₂, CuGaSe₂, CuGaS₂, Cu₂ZnSnS₄, Cu₂ZnSnSe₄, Bi₂Te₃, Sb₂Te₃, ZnO, ZnTe, CdTe, CdSe, CdS, SnS, SnSe, TiO₂, CsPbBr₃, CsPbI₃, AgGaSe₂, AgGaS₂, a molybdenum disulfide two-dimensional material, a carbon nanotube, mercury telluride, or combinations thereof.

11. The device structure of claim 10, further comprising:
a third metal electrode on the transparent substrate; and
an insulating layer on the transparent substrate, wherein the third metal electrode is separated from the first metal electrode and the second metal electrode by the insulating layer, a semiconductor layer projection of the semiconductor layer on the transparent substrate has a middle portion between a first metal electrode projection of the first metal electrode on the transparent substrate and a second metal electrode projection of the second metal electrode on the transparent substrate, the third metal electrode has a third metal electrode projection on the transparent substrate, and all the middle portion overlaps with the third metal electrode projection.

12. The device structure of claim 10, further comprising:
at least one third metal electrode on the transparent substrate, wherein the semiconductor layer has a middle portion between the first metal electrode and the second metal electrode, the middle portion comprises at least one first portion and at least one second portion, a projection of the at least one first portion on the transparent substrate does not overlap with a third metal electrode projection of the at least one third metal electrode on the transparent substrate, and a projection of the at least one second portion on the transparent substrate overlaps with the third metal electrode projection; and
an insulating layer on the transparent substrate, wherein the at least one third metal electrode is separated from the first metal electrode and the second metal electrode by the insulating layer.

13. A method of sensing infrared light, comprising:
irradiating the device structure of claim 10 with a light source, wherein the light source is incident towards a side of the semiconductor layer facing the transparent substrate; and
adjusting a first intensity of the light source to a second intensity to adjust a first energy barrier on a contact surface of the semiconductor layer with the first metal electrode and the second metal electrode to a second energy barrier, wherein the second intensity is larger than the first intensity, and the second energy barrier is smaller than the first energy barrier.

14. A method of sensing infrared light, comprising:
irradiating the device structure of claim 11 with a light source;
applying a positive bias voltage or a negative bias voltage to the third metal electrode; and
adjusting a first intensity of the light source to a second intensity to adjust a first energy barrier on a contact surface of the semiconductor layer with the first metal electrode and the second metal electrode to a second energy barrier, wherein the second intensity is larger than the first intensity, and the second energy barrier is smaller than the first energy barrier.

15. A method of sensing infrared light, comprising:
irradiating the device structure of claim 12 with a light source;
applying a positive bias voltage or a negative bias voltage to the at least one third metal electrode; and
adjusting a first intensity of the light source to a second intensity to adjust a first energy barrier on a contact surface of the semiconductor layer with the first metal electrode and the second metal electrode to a second energy barrier and to adjust a third energy barrier on a contact surface between the at least one first portion and the at least one second portion to a fourth energy barrier, wherein the second intensity is larger than the first intensity, the second energy barrier is smaller than the first energy barrier, and the fourth energy barrier is smaller than the third energy barrier.
